(19) United States
(12) Patent Application Publication
(10) Pub. No.: US 2023/0262980 A1
(43) Pub. Date: Aug. 17, 2023

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Seungjae Sim, Hwaseong-si (KR); Byung-Sun Park, Suwon-si (KR); Jaechul Lee, Hwaseong-si (KR); Dae-Hun Choi, Hwaseong-si (KR)

(21) Appl. No.: 17/936,473

(22) Filed: Sep. 29, 2022

(30) Foreign Application Priority Data
Feb. 16, 2022 (KR) 10-2022-0019997

(51) Int. Cl. H01L 27/11582; H01L 23/535; H01L 27/11573

(52) U.S. Cl. CPC H01L 27/11582; H01L 23/535; H01L 27/11573

(57) ABSTRACT

Disclosed are a three-dimensional semiconductor memory device, a method of fabricating the same, and an electronic system including the same. The semiconductor memory device may include a substrate including a first region and a second region, a plurality of stacks including first and second stacks, each of which includes interlayer insulating layers and gate electrodes stacked alternately with the interlayer insulating layers on the substrate and has a stepped structure on the second region, an insulating layer on stepped structure of the first stack, a plurality of vertical channel structures provided on the first region to penetrate the first stack, and a separation structure separating the first and second stacks from each other. The insulating layer may include one or more dopants, and a dopant concentration of the insulating layer may decrease as a distance from the substrate increases.

### CROSS-REFERENCE TO RELATED APPLICATION

This U.S. non-provisional patent application claims priority under 35 U.S.C. § 119 to Korean Patent Application No. 10-2022-0019997, filed on Feb. 16, 2022, in the Korean Intellectual Property Office, the entire contents of which are hereby incorporated by reference.

### BACKGROUND OF THE INVENTION

The present disclosure relates to a three-dimensional semiconductor memory device and an electronic system including the same, and in particular, a nonvolatile three-dimensional semiconductor memory device including a vertical channel structure, a method of fabricating the same, and an electronic system including the same.

A semiconductor device capable of storing a large amount of data may be used as a data storage of an electronic system. Higher integration of semiconductor devices may be beneficial to satisfy consumer demands for large data storing capacity, superior performance, and inexpensive prices. In the case of two-dimensional or planar semiconductor devices, since their integration density may depend on the area occupied by a unit memory cell, the integration density may be greatly influenced by a fine patterning technology. However, extremely expensive processes and/or equipment for fine patterning may limit an increase in the integration density of two-dimensional or planar semiconductor devices. Thus, three-dimensional semiconductor memory devices including three-dimensionally arranged memory cells have recently been proposed.

### SUMMARY

An embodiment of the inventive concept provides a three-dimensional semiconductor memory device with improved electrical and reliability characteristics and a method capable of simplifying a process of fabricating a three-dimensional semiconductor memory device.

An embodiment of the inventive concept provides an electronic system including the three-dimensional semiconductor memory device.

According to an embodiment of the inventive concept, a three-dimensional semiconductor memory device may include a substrate including a first region and a second region, a plurality of stacks including first and second stacks, each of which includes interlayer insulating layers and gate electrodes stacked alternately with the interlayer insulating layers on the substrate and has a stepped structure on the second region, an insulating layer provided on the stepped structure of the first stack, a plurality of vertical channel structures provided on the first region to penetrate the first stack, and a separation structure separating the first and second stacks from each other. The insulating layer may include one or more dopants, and a dopant concentration of the insulating layer may decrease as a distance from the substrate increases.

According to an embodiment of the inventive concept, a three-dimensional semiconductor memory device may include a first substrate including a first region and a second region, a peripheral circuit structure including peripheral circuit transistors provided on the first substrate, a second substrate provided on the peripheral circuit structure and on the first region and the second region of the first substrate, lower insulating patterns in the second substrate, a plurality of stacks including first and second stacks, each of which includes interlayer insulating layers and gate electrodes stacked alternately with the interlayer insulating layers on the second substrate and the lower insulating patterns and has a stepped structure on the second region, a source structure between the second substrate and the first stack, an insulating layer provided on the stepped structure of the first stack, a plurality of vertical channel structures provided on the first region of the first stack, penetrate the first stack and in contact with the second substrate, a plurality of first contact plugs, which are provided on the second region, and each of which penetrates the insulating layer, the first stack, the source structure, and one of the lower insulating patterns, are respectively connected to first ones of the peripheral circuit transistors of the peripheral circuit structure, and are respectively in contact with one of the gate electrodes of the first stack, a second contact plug that is provided on the second region to penetrate the insulating layer and is connected to a second one of the peripheral circuit transistors of the peripheral circuit structure, and a separation structure separating the first and second stacks from each other and extending in a first direction. The separation structure may include opposing side surfaces, each of which comprises a recess, and the recesses of the opposing side surfaces of the separation structure are aligned with each other along a second direction crossing the first direction and define a narrow portion having a narrower width than adjacent portions thereof in the second direction. The insulating layer may include one or more dopants.

According to an embodiment of the inventive concept, an electronic system may include a three-dimensional semiconductor memory device and a controller, which is electrically connected to the three-dimensional semiconductor memory device and is configured to control the three-dimensional semiconductor memory device. The three-dimensional semiconductor memory device may include a substrate including a first region and a second region, a plurality of stacks including first and second stacks, each of which includes interlayer insulating layers and gate electrodes stacked alternately with the interlayer insulating layers on the substrate and has a stepped structure on the second region, an insulating layer provided on the stepped structure of the first stack, a plurality of vertical channel structures provided on the first region and penetrate the first stack, and a separation structure separating the first and second stacks from each other. The insulating layer may include one or more dopants, and a dopant concentration of the insulating layer may decrease as a distance from the substrate increases.

### BRIEF DESCRIPTION OF THE DRAWINGS

FIG. 1 is a schematic diagram illustrating an electronic system including a three-dimensional semiconductor memory device according to an embodiment of the inventive concept.

FIG. 2 is a perspective view schematically illustrating an electronic system including a three-dimensional semiconductor memory device according to an embodiment of the inventive concept.

FIGS. 3 and 4 are sectional views, which are respectively taken along lines I-I′ and II-II′ of FIG. 2 to illustrate a semiconductor package including a three-dimensional semiconductor memory device according to an embodiment of the inventive concept.

FIG. 5 is a plan view illustrating a three-dimensional semiconductor memory device according to an embodiment of the inventive concept.

FIGS. 6, 7, and 8 are sectional views, which are respectively taken along lines I-I′, II-II′, and III-III′ of FIG. 5 to illustrate a three-dimensional semiconductor memory device according to an embodiment of the inventive concept.

FIG. 9 is a graph showing a variation in doping concentration of an insulating layer covering a stack, in a three-dimensional semiconductor memory device according to an embodiment of the inventive concept.

FIG. 10 is an enlarged plan view illustrating a portion (e.g., A of FIG. 5) of a three-dimensional semiconductor memory device according to an embodiment of the inventive concept.

FIGS. 11A and 11B are enlarged sectional views illustrating a portion (e.g., B of FIG. 6) of a three-dimensional semiconductor memory device according to an embodiment of the inventive concept.

FIG. 12 is a sectional view illustrating a three-dimensional semiconductor memory device according to an embodiment of the inventive concept and corresponding to the line III-III′ of FIG. 5.

FIGS. 13 and 14 are sectional views illustrating a three-dimensional semiconductor memory device according to an embodiment of the inventive concept and corresponding to the lines I-I′ and II-II′ of FIG. 5.

FIG. 15 is a graph showing a variation in doping concentration of an insulating layer covering a stack, in a three-dimensional semiconductor memory device according to an embodiment of the inventive concept.

FIG. 16 is a plan view illustrating a three-dimensional semiconductor memory device according to an embodiment of the inventive concept.

FIGS. 17A, 18A, and 19A are plan views illustrating a method of fabricating a three-dimensional semiconductor memory device according to an embodiment of the inventive concept.

FIGS. 17B, 18B, and 19B are sectional views, which are respectively taken along lines I-I′ of FIGS. 17A, 18A, and 19A to illustrate a method of fabricating a three-dimensional semiconductor memory device according to an embodiment of the inventive concept.

FIG. 17C is a sectional view, which is taken along a line II-II′ of FIG. 17A to illustrate a method of fabricating a three-dimensional semiconductor memory device according to an embodiment of the inventive concept.

FIGS. 18C and 19C are sectional views, which are respectively taken along lines III-III′ of FIGS. 18A and 19A to illustrate a method of fabricating a three-dimensional semiconductor memory device according to an embodiment of the inventive concept.

### DETAILED DESCRIPTION

Example embodiments of the inventive concept will now be described more fully with reference to the accompanying drawings, in which example embodiments are shown.

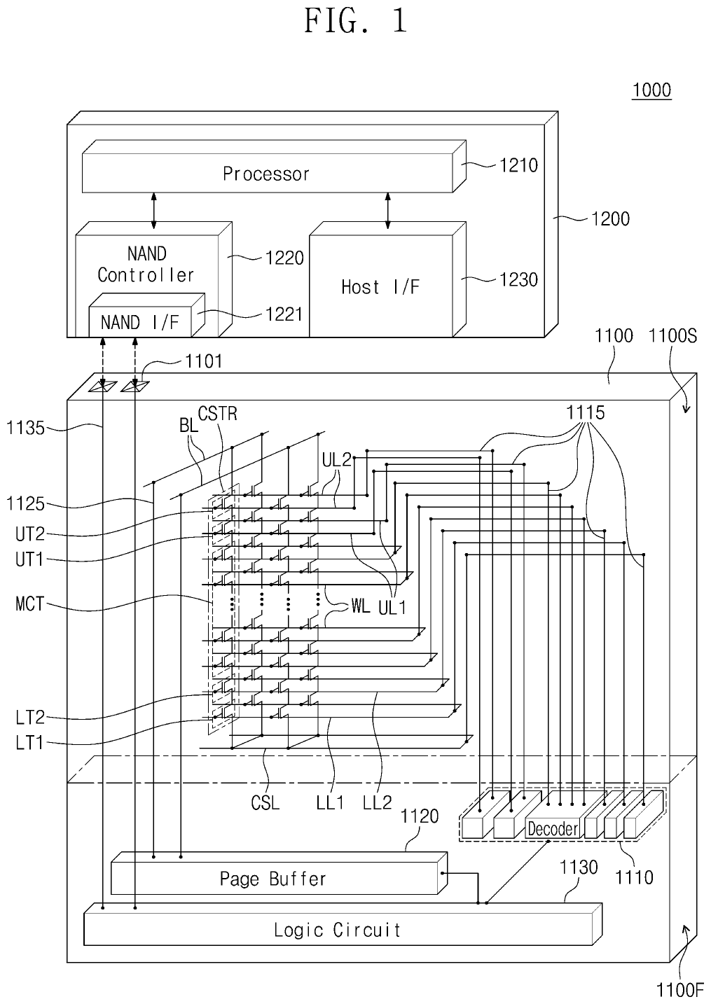

FIG. 1 is a schematic diagram illustrating an electronic system including a three-dimensional semiconductor memory device according to an embodiment of the inventive concept.

Referring to FIG. 1, an electronic system 1000 may include a three-dimensional semiconductor memory device 1100 and a controller 1200, which is electrically connected to the three-dimensional semiconductor memory device 1100. The electronic system 1000 may be a storage device including one or more three-dimensional semiconductor memory devices 1100 or an electronic device including such a storage device. For example, the electronic system 1000 may be a solid state drive (SSD) device, a universal serial bus (USB), a computing system, a medical system, or a communication system, in which at least one three-dimensional semiconductor memory device 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. In an embodiment, the first region 1100F may be disposed beside the second region 1100S. The first region 1100F may be a peripheral circuit region, which includes a decoder circuit 1110, a page buffer 1120, and a logic circuit 1130. The second region 1100S may be a memory cell region, which includes a bit line BL, a common source line CSL, word lines WL, first lines LL1 and LL2, second lines UL1 and UL2, and memory cell strings CSTR between the bit line BL and the common source line CSL.

In the second region 1100S, each of the memory cell strings CSTR may include first transistors LT1 and LT2 adjacent to the common source line CSL, second transistors UT1 and UT2 adjacent to the bit line BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments.

In an embodiment, the first transistors LT1 and LT2 may include a ground selection transistor, and the second transistors UT1 and UT2 may include a string selection transistor. The first lines LL1 and LL2 may be used as gate electrodes of the first transistors LT1 and LT2, respectively. The word lines WL may be used as gate electrodes of the memory cell transistors MCT. The second lines UL1 and UL2 may be used as gate electrodes of the second transistors UT1 and UT2, respectively.

In an embodiment, the first transistors LT1 and LT2 may include a first erase control transistor LT1 and a ground selection transistor LT2, which are connected in series. The second transistors UT1 and UT2 may include a string selection transistor UT1 and a second erase control transistor UT2, which are connected in series. At least one of the first and second erase control transistors LT1 and UT2 may be used for an erase operation of erasing data, which are stored in the memory cell transistors MCT, using a gate-induced drain leakage (GIDL) phenomenon.

The common source line CSL, the first lines LL1 and LL2, the word lines WL, and the second lines UL1 and UL2 may be electrically connected to the decoder circuit 1110 through first interconnection lines 1115, which extend from the first region 1100F to the second region 1100S. The bit line BL may be electrically connected to the page buffer 1120 through second interconnection lines 1125, which extend from the first region 1100F to the second region 1100S.

In the first region 1100F, the decoder circuit 1110 and the page buffer 1120 may be configured to perform a control operation, which is performed on at least one memory cell transistor selected from the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which extends from the first region 1100F to the second region 1100S.

The controller 1200 may include a processor 1210, a NAND controller 1220, and a host interface 1230. For example, the electronic system 1000 may include a plurality of three-dimensional semiconductor memory devices 1100, and in this case, the controller 1200 may control the plurality of three-dimensional semiconductor memory devices 1100.

The processor 1210 may control overall operations of the electronic system 1000 including the controller 1200. Based on a specific firmware, the processor 1210 may execute operations of controlling the NAND controller 1220 and accessing to the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands, which are used to control the three-dimensional semiconductor memory device 1100, data, which will be written in or read from the memory cell transistors MCT of the three-dimensional semiconductor memory device 1100, and so forth. The host interface 1230 may be configured to allow for communication between the electronic system 1000 and an external host. If a control command is provided from an external host through the host interface 1230, the processor 1210 may control the three-dimensional semiconductor memory device 1100.

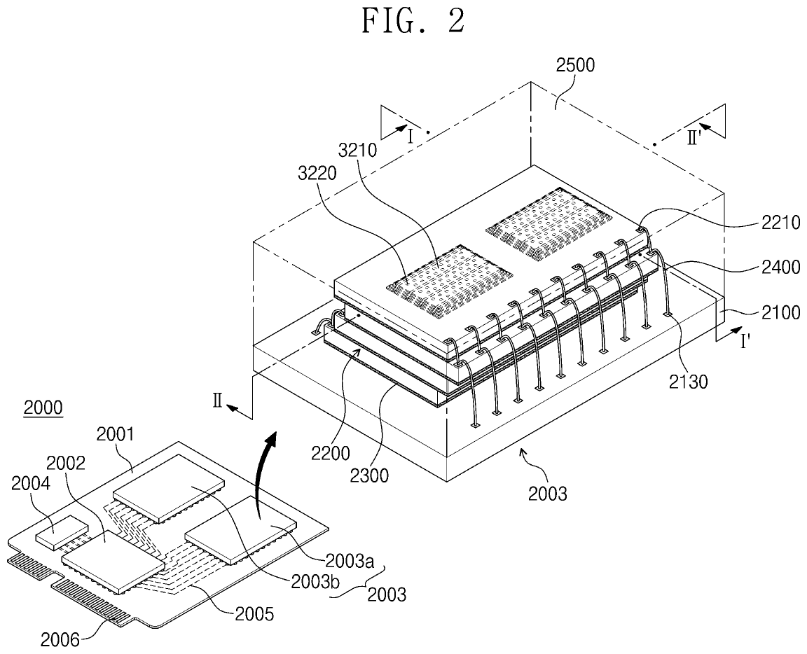

FIG. 2 is a perspective view schematically illustrating an electronic system including a three-dimensional semiconductor memory device according to an embodiment of the inventive concept.

Referring to FIG. 2, an electronic system 2000 may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 and may be connected to each other by interconnection patterns 2005, which are provided in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and the external host. In an embodiment, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stacks 3210 and vertical channel structures 3220. Each of the semiconductor chips 2200 may include a three-dimensional semiconductor memory device, which will be described below.

In an embodiment, the connection structure 2400 may be a bonding wire electrically connecting the input/output pads 2210 to the package upper pads 2130. In each of the first and second semiconductor packages 2003a and 2003b, the semiconductor chips 2200 may be electrically connected to each other in a bonding wire manner and may be electrically connected to the package upper pads 2130 of the package substrate 2100. In an embodiment, the semiconductor chips 2200 in each of the first and second semiconductor packages 2003a and 2003b may be electrically connected to each other by through silicon vias (TSVs), not by the connection structure 2400 provided in the form of bonding wires.

In an embodiment, the controller 2002 and the semiconductor chips 2200 may be included in a single package. For example, the controller 2002 and the semiconductor chips 2200 may be mounted on an interposer substrate, which is prepared independent of the main substrate 2001, and may be connected to each other through interconnection lines, which are provided in the interposer substrate.

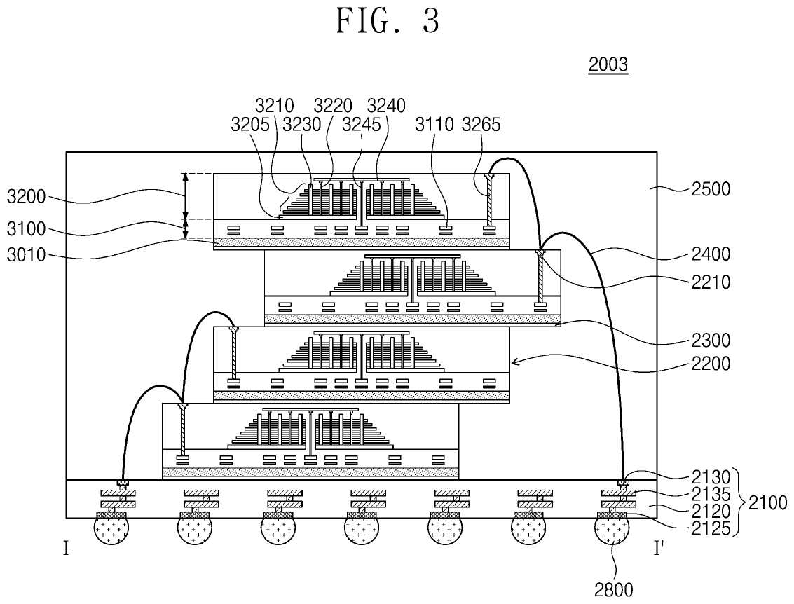

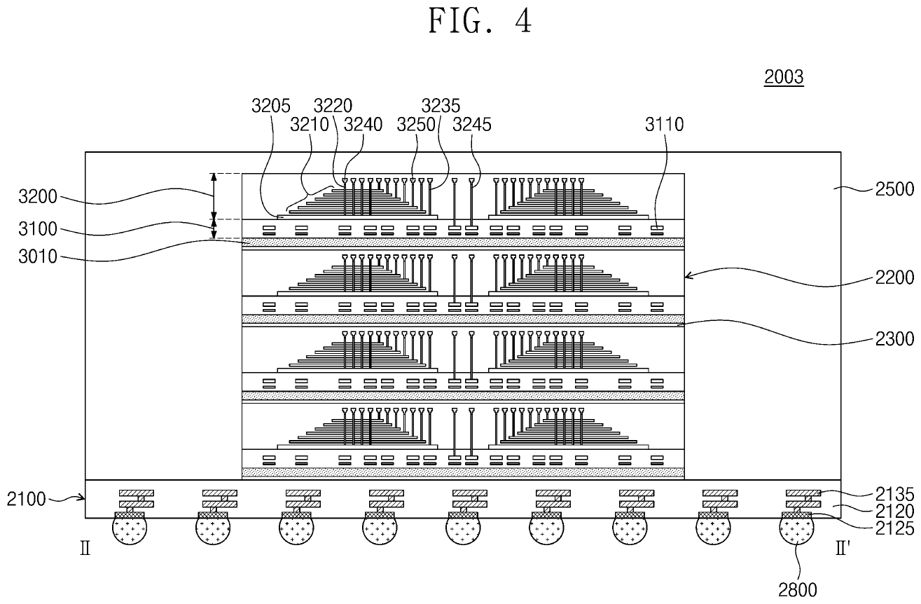

FIGS. 3 and 4 are sectional views, which are respectively taken along lines I-I′ and II-II′ of FIG. 2 to illustrate a semiconductor package including a three-dimensional semiconductor memory device according to an embodiment of the inventive concept.

Referring to FIGS. 3 and 4, the semiconductor package 2003 may include the package substrate 2100, a plurality of the semiconductor chips 2200 on the package substrate 2100, and the molding layer 2500 covering the package substrate 2100 and the semiconductor chips 2200.

The package substrate 2100 may include a package substrate body portion 2120, the package upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800.

Each of the semiconductor chips 2200 may include a semiconductor substrate 3010 and first and second structures 3100 and 3200, which are sequentially stacked on the semiconductor substrate 3010. The first structure 3100 may include a peripheral circuit region, in which peripheral lines 3110 are provided. The second structure 3200 may include a common source line 3205, a gate stack 3210 on the common source line 3205, vertical channel structures 3220 and separation structures 3230 penetrating the gate stack 3210, bit lines 3240 electrically connected to the vertical channel structures 3220, gate interconnection lines 3235 electrically connected to word lines (e.g., WL of FIG. 1) of the gate stack 3210, and conductive lines 3250.

Each of the semiconductor chips 2200 may include penetration lines 3245, which are electrically connected to the peripheral lines 3110 of the first structure 3100 and extend into the second structure 3200. The penetration line 3245 may be provided to penetrate the gate stack 3210, and in an embodiment, the penetration line 3245 may be further disposed outside the gate stack 3210. Each of the semiconductor chips 2200 may further include an input/output interconnection line 3265, which extends into the second structure 3200 and is electrically connected to the peripheral line 3110 of the first structure 3100, and the input/output pad 2210, which is electrically connected to the input/output interconnection line 3265.

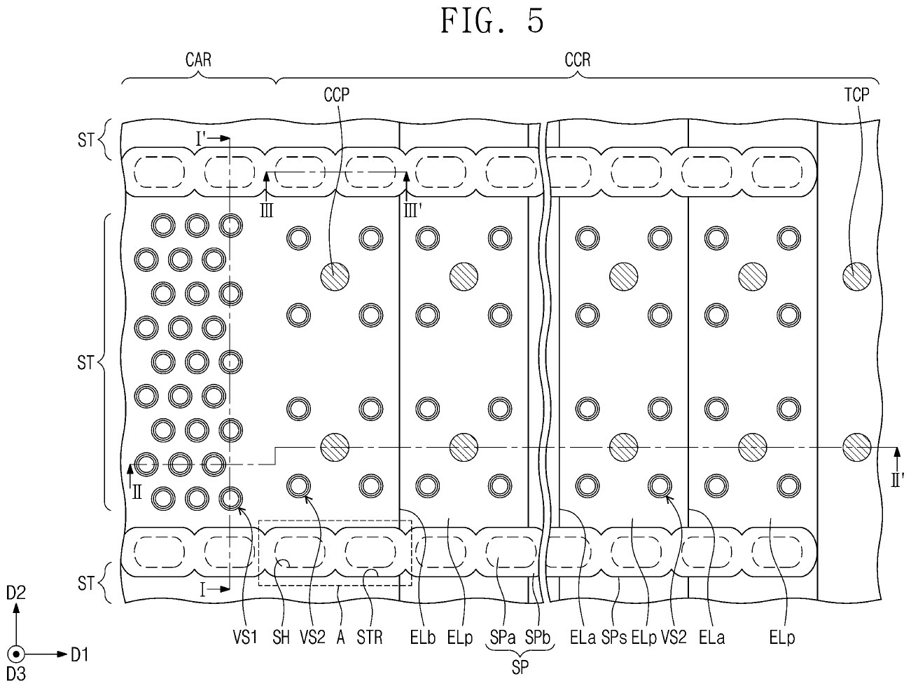

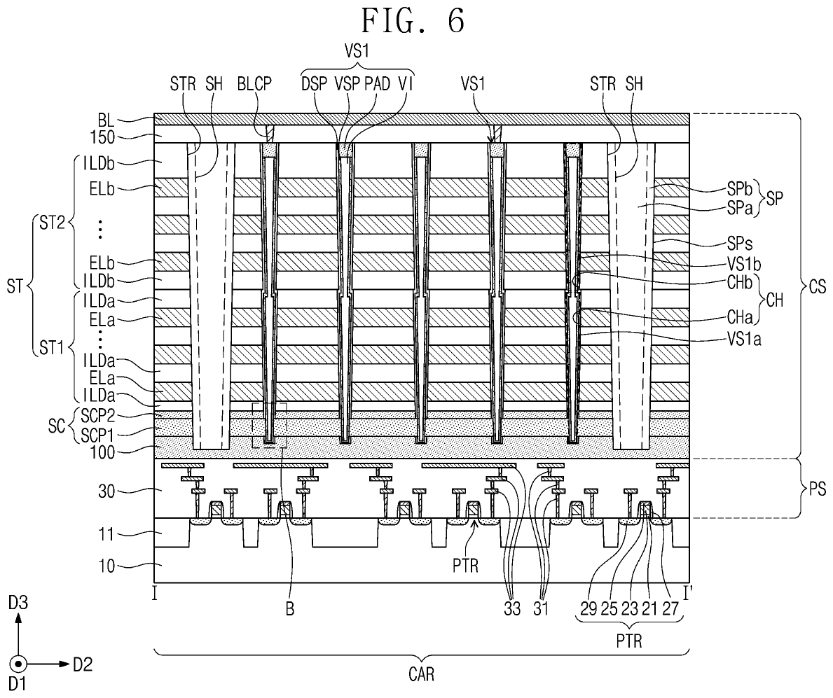

FIG. 5 is a plan view illustrating a three-dimensional semiconductor memory device according to an embodiment of the inventive concept. FIGS. 6, 7, and 8 are sectional views, which are respectively taken along lines I-I′, II-II′, and III-III′ of FIG. 5 to illustrate a three-dimensional semiconductor memory device according to an embodiment of the inventive concept.

Referring to FIGS. 5, 6, 7, and 8, a first substrate 10 including a first region CAR and a second region CCR may be provided. The first substrate 10 may extend in a first direction D1, which is oriented from the first region CAR toward the second region CCR, and in a second direction D2, which is not parallel to the first direction D1. Atop surface of the first substrate 10 may be perpendicular to a third direction D3 that is not parallel to the first and second directions D1 and D2. In an embodiment, the first, second, and third directions D1, D2, and D3 may be orthogonal to each other.

When viewed in a plan view, the second region CCR may extend from the first region CAR in the first direction D1. The first region CAR may be a region, in which the bit lines 3240 electrically connected to the vertical channel structures 3220, the separation structures 3230, and the vertical channel structures 3220 described with reference to FIGS. 3 and 4 will be provided. The second region CCR may be a region, in which a staircase structure including pad portions ELp to be described below will be provided. As used herein, “a staircase structure” may be interchangeable with “a stepped structure.”

In an embodiment, the first substrate 10 may be a silicon substrate, a silicon germanium substrate, a germanium substrate, or a structure including a single-crystalline silicon substrate and a single-crystalline epitaxial layer grown therefrom. A device isolation layer 11 may be provided in the first substrate 10. The device isolation layer 11 may be provided to define an active region of the first substrate 10. The device isolation layer 11 may be formed of or include, for example, silicon oxide.

A peripheral circuit structure PS may be provided on the first substrate 10. The peripheral circuit structure PS may include peripheral circuit transistors PTR on the active region of the first substrate 10, peripheral contact plugs 31, peripheral circuit interconnection lines 33 electrically connected to the peripheral circuit transistors PTR through the peripheral contact plugs 31, and a first insulating layer 30 enclosing them. The peripheral circuit structure PS may correspond to the first region 1100F of FIG. 1, and the peripheral circuit interconnection lines 33 may correspond to the peripheral lines 3110 of FIGS. 3 and 4.

The peripheral circuit transistors PTR, the peripheral contact plugs 31 and the peripheral circuit interconnection lines 33 may constitute a peripheral circuit. For example, the peripheral circuit transistors PTR may constitute the decoder circuit 1110, the page buffer 1120, and the logic circuit 1130 of FIG. 1. More specifically, each of the peripheral circuit transistors PTR may include a peripheral gate insulating layer 21, a peripheral gate electrode 23, a peripheral capping pattern 25, a peripheral gate spacer 27, and peripheral source/drain regions 29.

The peripheral gate insulating layer 21 may be provided between the peripheral gate electrode 23 and the first substrate 10. The peripheral capping pattern 25 may be provided on the peripheral gate electrode 23. The peripheral gate spacer 27 may cover side surfaces of the peripheral gate insulating layer 21, the peripheral gate electrode 23, and the peripheral capping pattern 25. The peripheral source/drain regions 29 may be provided in portions of the first substrate 10, which are located at both sides of the peripheral gate electrode 23.

The peripheral circuit interconnection lines 33 may be electrically connected to the peripheral circuit transistors PTR through the peripheral contact plugs 31. Each of the peripheral circuit transistors PTR may be an NMOS transistor or a PMOS transistor and, in an embodiment, it may be a gate-all-around type transistor. A width of each of the peripheral contact plugs 31 in the first or second direction D1 or D2 may increase as a distance from the first substrate 10 increases. The peripheral contact plugs 31 and the peripheral circuit interconnection lines 33 may be formed of or include at least one of conductive materials (e.g., metallic materials).

The first insulating layer 30 may be provided on the top surface of the first substrate 10. The first insulating layer 30 may be provided on the first substrate 10 to cover the peripheral circuit transistors PTR, the peripheral contact plugs 31, and the peripheral circuit interconnection lines 33. The first insulating layer 30 may be a multi-layered structure including a plurality of insulating layers. For example, the first insulating layer 30 may be formed of or include at least one of silicon oxide, silicon nitride, silicon oxynitride, and/or low-k dielectric materials. As used herein the term “and/or” includes any and all combinations of one or more of the associated listed items.

A cell array structure CS including a second substrate 100, a stack ST, first and second vertical channel structures VS1 and VS2, first and second contact plugs CCP and TCP may be provided on the peripheral circuit structure PS. Hereinafter, the structure of the cell array structure CS will be described in more detail.

The second substrate 100 and lower insulating patterns 101 may be provided on the first insulating layer 30. The second substrate 100 may extend in the first and second directions D1 and D2. The second substrate 100 may not be provided on a portion of the second region CCR. The second substrate 100 may be a semiconductor substrate including a semiconductor material. For example, the second substrate 100 may be formed of or include at least one of silicon (Si), germanium (Ge), silicon germanium (SiGe), gallium arsenic (GaAs), indium gallium arsenic (InGaAs), or aluminum gallium arsenic (AlGaAs).

The lower insulating patterns 101 may define positions of the first and second contact plugs CCP and TCP. The lower insulating patterns 101 may be provided between the first insulating layer 30 and a source structure SC to be described below. When viewed in a plan view, each of the lower insulating patterns 101 may be enclosed by the second substrate 100. A top surface of each of the lower insulating patterns 101 may be substantially coplanar with a top surface of the second substrate 100, and a bottom surface of each of the lower insulating patterns 101 may be substantially coplanar with a bottom surface of the second substrate 100 and a top surface of the first insulating layer 30. In an embodiment, the lower insulating patterns 101 may be formed of or include at least one of silicon oxide, silicon nitride, and/or silicon oxynitride.

The stack ST may be provided on the second substrate 100 and the lower insulating patterns 101. The stack ST may extend from the first region CAR to the second region CCR. The stack ST may correspond to the stacks 3210 of FIGS. 3 and 4. In an embodiment, a plurality of the stacks ST may be arranged in the second direction D2 and may be spaced apart from each other in the second direction D2 with a separation structure SP interposed therebetween. For brevity's sake, one of the stacks ST will be described below, but the others of the stacks ST may also have substantially the same features as described below.

The stack ST may include interlayer insulating layers ILDa and ILDb and gate electrodes ELa and ELb, which are alternately and repeatedly stacked. The gate electrodes ELa and ELb may correspond to the word lines WL, the first lines LL1 and LL2, and the second lines UL1 and UL2 of FIG. 1.

More specifically, the stack ST may include a first stack ST1 on the second substrate 100 and a second stack ST2 on the first stack ST1. The first stack ST1 may include first interlayer insulating layers ILDa and first gate electrodes ELa, which are alternately and repeatedly stacked, and the second stack ST2 may include second interlayer insulating layers ILDb and second gate electrodes ELb, which are alternately and repeatedly stacked. The first and second gate electrodes ELa and ELb may have substantially the same thickness in the third direction D3. Hereinafter, the term “thickness” may refer to a length of an element in the third direction D3. The first stack ST1 may be a lower stack, and the second stack ST2 may be an upper stack.

As a height from the second substrate 100 (i.e., in the third direction D3) increases, a length of each of the first and second gate electrodes ELa and ELb in the first direction D1 may decrease. That is, the length of each of the first and second gate electrodes ELa and ELb in the first direction D1 may be longer than a length of another electrode thereon in the first direction D1. The lowermost one of the first gate electrodes ELa of the first stack ST1 (i.e., the first gate electrode ELa closest to the second substrate 100) may have the longest length in the first direction D1, and the uppermost one of the second gate electrodes ELb of the second stack ST2 (i.e., the second gate electrode ELb farthest from the second substrate 100) may have the shortest length in the first direction D1.

The first and second gate electrodes ELa and ELb may have the pad portions ELp, which are provided on the second region CCR. The pad portions ELp of the first and second gate electrodes ELa and ELb may be disposed at positions that are different from each other in horizontal and vertical directions. A thickness of each of the pad portions ELp may be larger than a thickness of other portion (i.e., an electrode portion) of each of the first and second gate electrodes ELa and ELb. A top surface of each of the pad portions ELp may be located at a level that is higher than a top surface of other portion of each of the first and second gate electrodes ELa and ELb. Each of the pad portions ELp may cover at least a portion of a side surface of an interlayer insulating layer placed thereon.

The pad portions ELp may be provided to form a staircase structure in the first direction D1. Due to the staircase structure, each of the first and second stacks ST1 and ST2 may have a decreasing thickness as a distance from first vertical channel structures VS1 (to be described below) increases, and side surfaces of the first and second gate electrodes ELa and ELb may be spaced apart from each other by a substantially constant distance in the first direction D1, when viewed in a plan view.

The first and second gate electrodes ELa and ELb may be formed of or include at least one of, for example, doped semiconductor materials (e.g., doped silicon and so forth), metallic materials (e.g., tungsten, copper, aluminum, and so forth), conductive metal nitrides (e.g., titanium nitride, tantalum nitride, and so forth), or transition metals (e.g., titanium, tantalum, and so forth).

The first and second interlayer insulating layers ILDa and ILDb may be provided between the first and second gate electrodes ELa and ELb, and each of them may have a side surface that is aligned to a side surface of a corresponding one of the first and second gate electrodes ELa and ELb, which is disposed thereunder and is in contact therewith. Similar to the first and second gate electrodes ELa and ELb, as a height from the second substrate 100 increase, lengths of the first and second interlayer insulating layers ILDa and ILDb in the first direction D1 may decrease.

The lowermost one of the second interlayer insulating layers ILDb may be in contact with the uppermost one of the first interlayer insulating layers ILDa. In an embodiment, a thickness of each of the first and second interlayer insulating layers ILDa and ILDb may be smaller than a thickness of each of the first and second gate electrodes ELa and ELb. In an embodiment, the lowermost one of the first interlayer insulating layers ILDa may have a thickness that is smaller than those of the remaining ones of the interlayer insulating layers ILDa and ILDb. In addition, the uppermost and lowermost ones of the second interlayer insulating layers ILDb may be thicker than the others of the interlayer insulating layers ILDa and ILDb.

Except for the lowermost one of the first interlayer insulating layers ILDa and the uppermost and lowermost ones of the second interlayer insulating layers ILDb, the remaining ones of the interlayer insulating layers ILDa and ILDb may have substantially the same thickness. However, the inventive concept is not limited to this example, and the thicknesses of the first and second interlayer insulating layers ILDa and ILDb may be variously changed, depending on technical properties required for each semiconductor device.

The first and second interlayer insulating layers ILDa and ILDb may be formed of or include at least one of insulating materials. In an embodiment, the first and second interlayer insulating layers ILDa and ILDb may be formed of or include at least one of doped insulating materials. The first and second interlayer insulating layers ILDa and ILDb may be formed of or include at least one of doped silicon oxide, doped silicon nitride, doped silicon oxynitride, and/or doped low-k dielectric materials. In an embodiment, the first and second interlayer insulating layers ILDa and ILDb may be doped with one or more dopants (e.g., N, F, P, B, C, Ge, As, Cl, and/or Br).

A source structure SC may be provided between the second substrate 100 and the lowermost one of the first interlayer insulating layers ILDa. The source structure SC may correspond to the common source line CSL of FIG. 1 and the common source line 3205 of FIGS. 3 and 4. The source structure SC may extend parallel to the first and second gate electrodes ELa and ELb of the stack ST or in the first and second directions D1 and D2. The source structure SC may include a first source conductive pattern SCP1 and a second source conductive pattern SCP2 sequentially stacked. The second source conductive pattern SCP2 may be provided between the first source conductive pattern SCP1 and the lowermost one of the first interlayer insulating layers ILDa. A thickness of the first source conductive pattern SCP1 may be larger than a thickness of the second source conductive pattern SCP2. Each of the first and second source conductive patterns SCP1 and SCP2 may be formed of or include at least one of doped semiconductor materials. A doping concentration of the first source conductive pattern SCP1 may be different from a doping concentration of the second source conductive pattern SCP2. For example, the doping concentration of the first source conductive pattern SCP1 may be higher than the doping concentration of the second source conductive pattern SCP2.

A plurality of first vertical channel structures VS1 may be provided on the first region CAR to penetrate the stack ST and the source structure SC. The first vertical channel structures VS1 may be provided to penetrate at least a portion of the second substrate 100, and a bottom surface of each of the first vertical channel structures VS1 may be located at a level lower than the top surface of the second substrate 100 and the bottom surface of the source structure SC.

The first vertical channel structures VS1 may be arranged to form a zigzag shape in the first or second direction D1 or D2, when viewed in the plan view of FIG. 5. The first vertical channel structures VS1 may not be provided on the second region CCR. The first vertical channel structures VS1 may correspond to the vertical channel structures 3220 of FIGS. 2 to 4. The first vertical channel structures VS1 may correspond to the channel regions of the first transistors LT1 and LT2, the memory cell transistors MCT, and the second transistors UT1 and UT2 of FIG. 1.

The first vertical channel structures VS1 may be provided in vertical channel holes CH penetrating the stack ST. Each of the vertical channel holes CH may include a first vertical channel hole CHa, which is formed to penetrate the first stack ST1, and a second vertical channel hole CHb, which is formed to penetrate the second stack ST2. The first and second vertical channel holes CHa and CHb of each of the vertical channel holes CH may be connected to each other in the third direction D3.

Each of the first vertical channel structures VS1 may include a first portion VS1a and a second portion VS1b. The first portion VS1a may be provided in the first vertical channel hole CHa, and the second portion VS1b may be provided in the second vertical channel hole CHb. The second portion VS1b may be provided on and connected to the first portion VS1a.

For each of the first and second portions VS1a and VS1b, a width in the first or second direction D1 or D2 may increase with increasing distance from the second substrate 100 in the third direction D3. The uppermost width of the first portion VS1a (i.e., the width of the uppermost portion of the first portion VS1a) may be larger than the lowermost width of the second portion VS1b (i.e., the width of the lowermost portion of the second portion VS1b). In other words, a side surface of each of the first vertical channel structures VS1 may have a stepped structure near a boundary between the first portion VS1a and the second portion VS1b. However, the inventive concept is not limited to this example, and in an embodiment, the side surface of each of the first vertical channel structures VS1 may have three or more stepped portions at different levels or may have a flat shape without a stepped portion.

Each of the first vertical channel structures VS1 may include a data storage pattern DSP, which is adjacent to the stack ST (i.e., covering an inner side surface of each of the vertical channel holes CH), a vertical semiconductor pattern VSP, which is provided to conformally cover an inner side surface of the data storage pattern DSP, a gapfill insulating pattern VI, which is provided to fill an internal space delimited by the vertical semiconductor pattern VSP, and a conductive pad PAD, which is provided on the gapfill insulating pattern VI and the vertical semiconductor pattern VSP and is provided in a space delimited by the data storage pattern DSP. In an embodiment, a top surface of each of the first vertical channel structures VS1 may have a circular, elliptical, or bar shape.

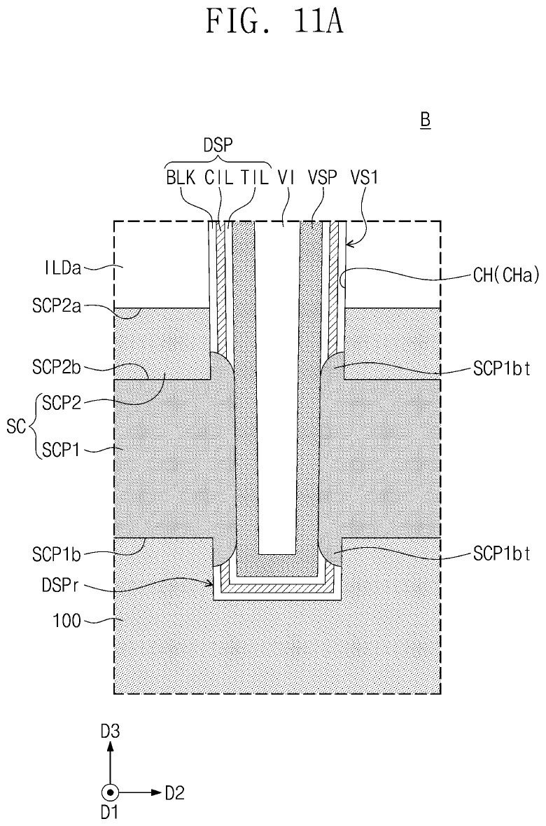

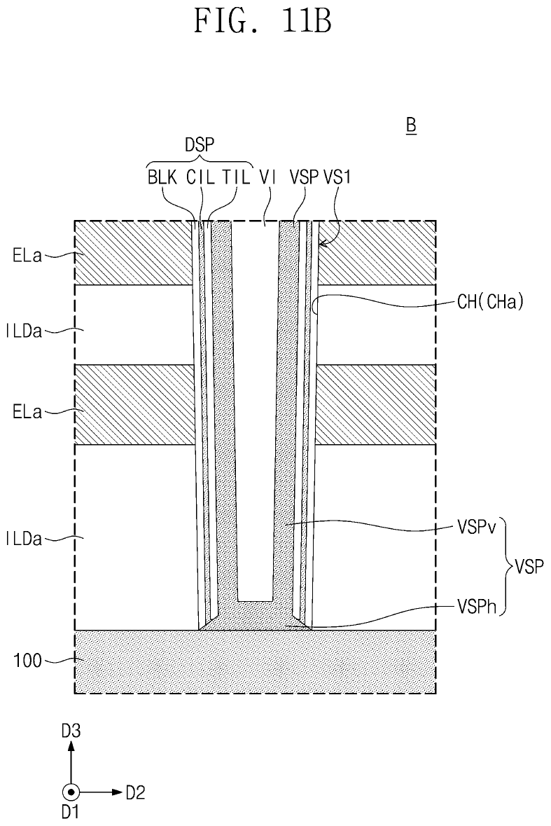

The vertical semiconductor pattern VSP may be provided between the data storage pattern DSP and the gapfill insulating pattern VI. The vertical semiconductor pattern VSP may be shaped like a bottom-closed pipe or macaroni. The data storage pattern DSP may be shaped like a bottom-opened pipe or macaroni. The vertical semiconductor pattern VSP may be formed of or include at least one of doped semiconductor materials or undoped or intrinsic semiconductor materials and may have a poly-crystalline structure. As will be described with reference to FIG. 11A, the vertical semiconductor pattern VSP may be in contact with a portion of the source structure SC. In an embodiment, the conductive pad PAD may be formed of or include at least one of doped semiconductor materials or conductive materials.

A plurality of second vertical channel structures VS2 may be provided on the second region CCR to penetrate second and third insulating layers 110 and 130 (to be described below), the stack ST, and the source structure SC. More specifically, the second vertical channel structures VS2 may be provided to penetrate the pad portions ELp of the first and second gate electrodes ELa and ELb. The second vertical channel structures VS2 may be provided near first contact plugs CCP, which will be described below. The second vertical channel structures VS2 may not be provided on the first region CAR. The first and second vertical channel structures VS1 and VS2 may be formed at the same time and may have substantially the same structure. However, in an embodiment, the second vertical channel structures VS2 may not be provided.

A second insulating layer 110 may be provided on the second region CCR to partially cover the first stack ST1 and the second substrate 100. More specifically, the second insulating layer 110 may be provided on the pad portions ELp of the first gate electrodes ELa to cover the staircase structure of the first stack ST1. The second insulating layer 110 may have a substantially flat top surface. A top surface of the second insulating layer 110 may be substantially coplanar with the uppermost surface of the first stack ST1. More specifically, the top surface of the second insulating layer 110 may be substantially coplanar with a top surface of the uppermost one of the first interlayer insulating layers ILDa of the first stack ST1.

A third insulating layer 130 may be provided on the second region CCR to cover the second stack ST2 and the second insulating layer 110. More specifically, the third insulating layer 130 may be provided on the pad portions ELp of the second gate electrodes ELb to cover the staircase structure of the second stack ST2. The third insulating layer 130 may have a substantially flat top surface. A top surface of the third insulating layer 130 may be substantially coplanar with the uppermost surface of the second stack ST2. More specifically, the top surface of the third insulating layer 130 may be substantially coplanar with a top surface of the uppermost one of the second interlayer insulating layers ILDb of the second stack ST2.

The lowermost surface of the second insulating layer 110 may be located at a first level Lv1, and the uppermost surface of the third insulating layer 130 may be located at a second level Lv2. The uppermost surface of the second insulating layer 110 and the lowermost surface of the third insulating layer 130 may be located at a third level Lv3 between the first level Lv1 and the second level Lv2. The first level Lv1 may be the same level as the top surface of the first insulating layer 30, and the second level Lv2 may be the same level as the uppermost surface of the stack ST including the first and second stacks ST1 and ST2. In an embodiment, a side surface of each of the first and second vertical channel structures VS1 and VS2 may have a stepped portion at the third level Lv3.

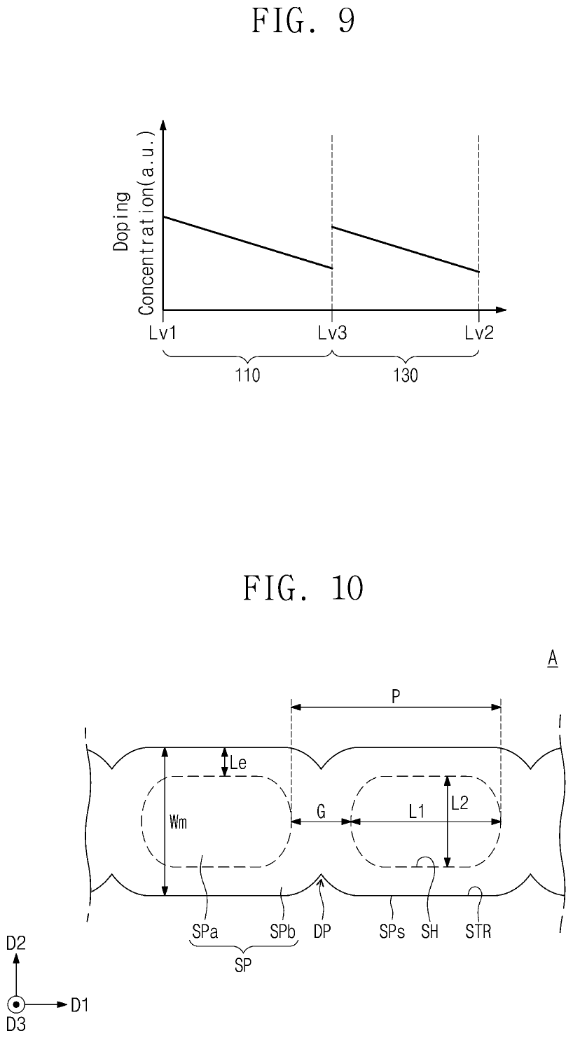

Each of the second and third insulating layers 110 and 130 may include an insulating layer or a plurality of insulating layers stacked. The second and third insulating layers 110 and 130 may be formed of or include at least one of doped insulating materials. The second and third insulating layers 110 and 130 may be formed of or include at least one of doped silicon oxide, doped silicon nitride, doped silicon oxynitride, and/or doped low-k dielectric materials. The second and third insulating layers 110 and 130 may contain an impurity (e.g., N, F, P, B, C, Ge, As, Cl, and/or Br). The impurity may be referred to as dopants. In an embodiment, a doping concentration in the second and third insulating layers 110 and 130 may not be uniform, as will be described with reference to FIG. 9.

The second and third insulating layers 110 and 130 may be formed of or include an insulating material that is different from the first and second interlayer insulating layers ILDa and ILDb of the stack ST. For example, in the case where the first and second interlayer insulating layers ILDa and ILDb of the stack ST include high density plasma oxide, the second and third insulating layers 110 and 130 may be formed of or include tetraethyl orthosilicate (TEOS).

A fourth insulating layer 150 may be provided on the third insulating layer 130 and the stack ST. The fourth insulating layer 150 may cover the top surface of the third insulating layer 130, the top surface of the uppermost one of the second interlayer insulating layers ILDb of the stack ST, and the top surfaces of the first and second vertical channel structures VS1 and VS2.

The fourth insulating layer 150 may include a single insulating layer or a plurality of insulating layers stacked. The fourth insulating layer 150 may be formed of or include at least one of silicon oxide, silicon nitride, silicon oxynitride, and/or low-k dielectric materials. In an embodiment, the fourth insulating layer 150 may be formed of or include an insulating material that is substantially the same as the second and third insulating layers 110 and 130 but is different from the first and second interlayer insulating layers ILDa and ILDb of the stack ST.

Bit line contact plugs BLCP may be provided on the first region CAR to penetrate the fourth insulating layer 150 and may be connected to the first vertical channel structures VS1. Each of the bit line contact plugs BLCP may be electrically connected to the conductive pad PAD of a corresponding one of the first vertical channel structures VS1. The bit line contact plugs BLCP may be spaced apart from each other.

Each of the first contact plugs CCP may be provided to penetrate the fourth insulating layer 150, at least a portion of the second and third insulating layers 110 and 130, the stack ST, the source structure SC, and a corresponding one of the lower insulating patterns 101. Each of the first contact plugs CCP may be in contact with a corresponding one of the peripheral circuit interconnection lines 33 of the peripheral circuit structure PS and may be electrically connected to a corresponding one of the peripheral circuit transistors PTR. Each of the first contact plugs CCP may be adjacent to, but spaced apart from, the second vertical channel structures VS2. A height of each of the first contact plugs CCP in the third direction D3 may be larger than a height of the stack ST in the third direction D3. A top surface of each of the first contact plugs CCP may be substantially coplanar with a top surface of the fourth insulating layer 150. A bottom surface of each of the first contact plugs CCP may be located at a level lower than the bottom surface of the second substrate 100 and the bottom surfaces of the lower insulating patterns 101. The first contact plugs CCP may correspond to the gate interconnection lines 3235 of FIG. 4.

Each of the first contact plugs CCP may be electrically connected to and in contact with a corresponding one of the first and second gate electrodes ELa and ELb (i.e., a portion of the pad portions ELp exposed by the staircase structure). Each of the first contact plugs CCP may be horizontally spaced apart from the first and second gate electrodes ELa and ELb and the source structure SC, which are placed below the pad portions ELp, with insulating separation patterns IP interposed therebetween. In other words, each of the first contact plugs CCP may be electrically connected to a corresponding one of the first and second gate electrodes ELa and ELb and may be electrically disconnected from the others of the gate electrodes ELa and ELb.

A second contact plug TCP may be provided to penetrate the second to fourth insulating layers 110, 130, and 150 and at least a portion of the first insulating layer 30 and to be electrically connected to the peripheral circuit transistors PTR of the peripheral circuit structure PS. The second contact plug TCP may be spaced apart from the second substrate 100, the source structure SC, and the stack ST in the first direction D1. A height of the second contact plug TCP in the third direction D3 may be substantially equal to a height of each of the first contact plugs CCP in the third direction D3. A top surface of the second contact plug TCP may be substantially coplanar with the top surface of the fourth insulating layer 150. A bottom surface of the second contact plug TCP may be located at a level lower than the bottom surface of the second substrate 100 and the bottom surfaces of the lower insulating patterns 101. The second contact plug TCP may correspond to the penetration line 3245 or the input/output interconnection line 3265 of FIGS. 3 and 4. In an embodiment, a plurality of second contact plugs TCP may be provided.

For the bit line contact plugs BLCP, the first contact plugs CCP, and the second contact plug TCP, a width in the first or second direction D1 or D2 may increase as a height in the third direction D3 increases.

Bit lines BL may be provided on the fourth insulating layer 150 and may be connected to corresponding ones of the bit line contact plugs BLCP. The bit lines BL may correspond to the bit line BL of FIG. 1 or the bit lines 3240 of FIGS. 3 and 4.

First conductive lines CL1 and second conductive line CL2, which are connected to the first contact plugs CCP and the second contact plug TCP, may be provided on the fourth insulating layer 150. The first and second conductive lines CL1 and CL2 may correspond to the conductive lines 3250 of FIG. 4. In an embodiment, the second conductive line CL2 may be electrically connected to an element that is used as the input/output pad 1101 of FIG. 1 or the input/output pads 2210 of FIGS. 2 and 3.

The bit line contact plugs BLCP, the first contact plugs CCP, the second contact plug TCP, the bit lines BL, and the first and second conductive lines CL1 and CL2 may be formed of or include at least one of conductive materials (e.g., metallic materials). In an embodiment, additional interconnection lines and additional vias, which are electrically connected to the bit lines BL and the first and second conductive lines CL1 and CL2, may be further provided on the fourth insulating layer 150.

In the case where a plurality of stacks ST are provided, a separation structure SP extending in the first direction D1 may be provided between the stacks ST. The separation structure SP may correspond to the separation structures 3230 of FIGS. 3 and 4. The separation structure SP may be spaced apart from the first and second vertical channel structures VS1 and VS2 in the second direction D2. The separation structure SP may be formed of or include at least one of insulating materials (e.g., silicon oxide, silicon nitride, or silicon oxynitride). In an embodiment, the separation structure SP may have a single object structure, which is formed of a single insulating material. The separation structure SP may be formed of or include the same insulating material as the first and second interlayer insulating layers ILDa and ILDb, but the inventive concept is not limited to this example.

In an embodiment, a plurality of separation structures SP may be provided, and the separation structures SP may be spaced apart from each other in the second direction D2 with the stack ST interposed therebetween. For brevity's sake, one of the separation structures SP will be described below, but the others of the separation structures SP may also have substantially the same features as described below.

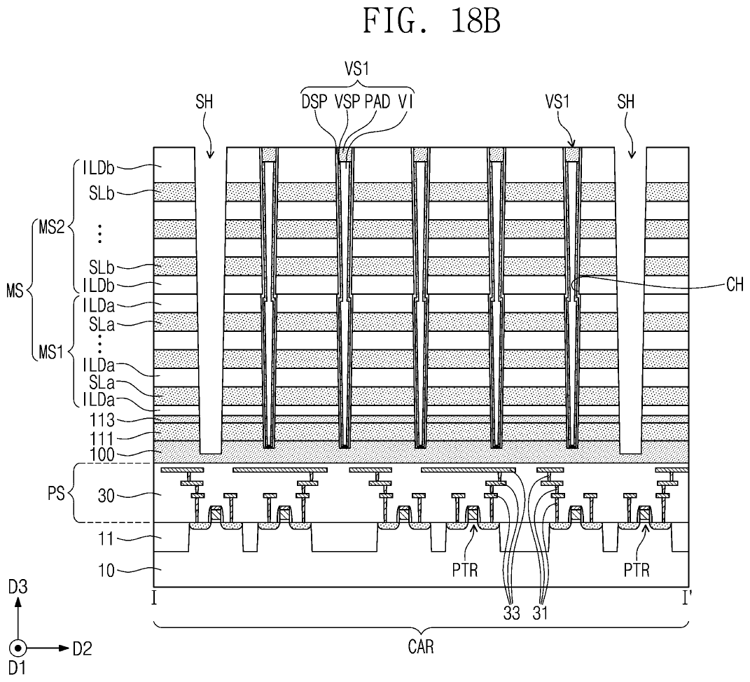

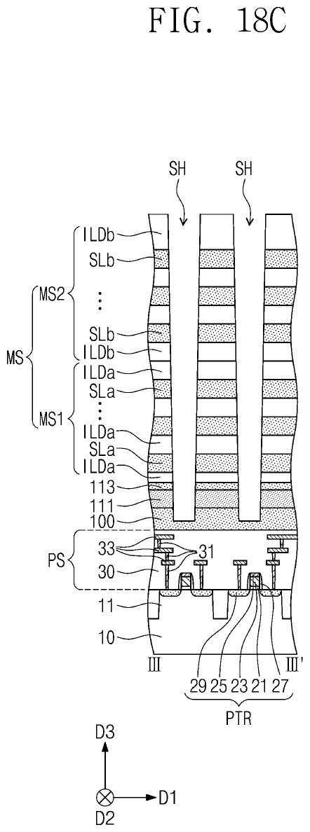

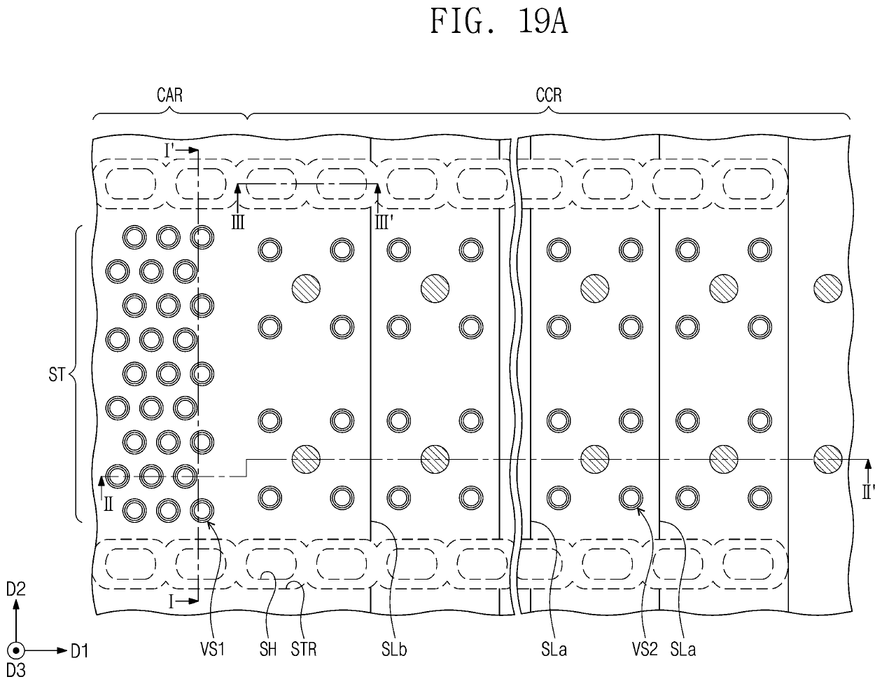

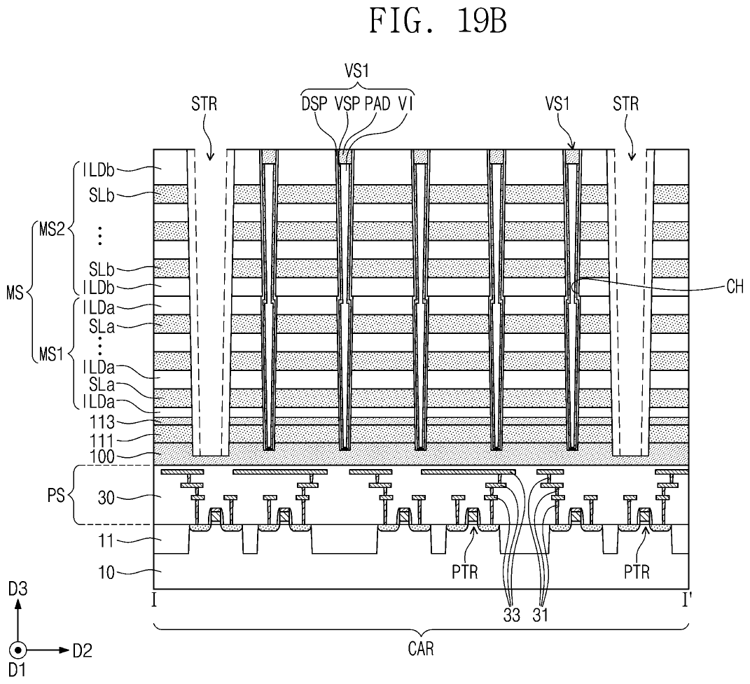

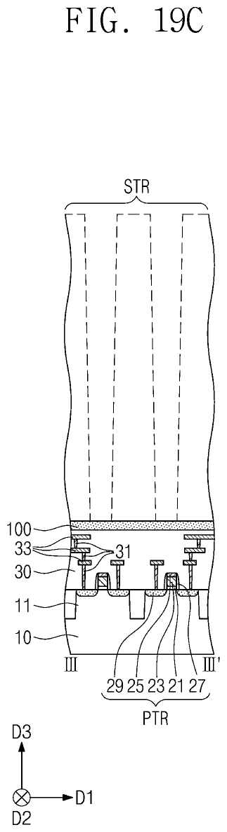

The separation structure SP may include first portions SPa, which are provided to fill separation holes SH (to be described with reference to FIGS. 18A to 18C) and to have a pillar shape extending from the second substrate 100 in the third direction D3, and a second portion SPb, which is provided to enclose the first portions SPa in a plan view and to connect the first portions SPa to each other. The second portion SPb may be provided to fill a separation trench STR, which will be described with reference to FIGS. 19A to 19C.

Similar to the separation holes SH, a width, in the first or second direction D1 or D2, of each of the first portions SPa may increase as a height in the third direction D3 from the second substrate 100 increases. In other words, an upper width of each of the first portions SPa may be larger than a lower width of each of the first portions SPa. The first portions SPa may be spaced apart from each other in the first direction D1.

The second portion SPb may extend from a side surface of each of the first portions SPa in a horizontal direction. Hereinafter, the horizontal direction may mean a direction parallel to the first and second directions D1 and D2. The second portion SPb may be provided to enclose the first portions SPa. The first portions SPa, which are adjacent to each other in the first direction D1, may be connected to each other through the second portion SPb, thereby forming a single object structure. Since the first portions SPa form a single object structure (i.e., a unitary structure) by the second portion SPb, the separation structure SP may extend in the first direction D1 to separate the stacks ST from each other, when viewed in the plan view of FIG. 5. In some embodiments, the separation structure SP may separate two stacks ST that are adjacent to each other and spaced apart from etch other in the second direction D2 as illustrated in FIG. 5.

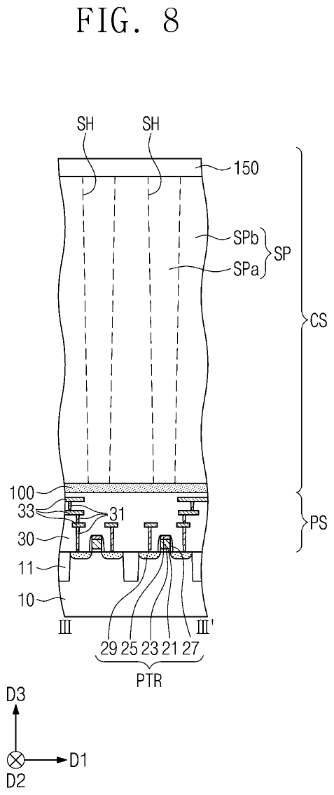

Referring to FIG. 8, the second portion SPb may fully cover a portion of the top surface of the second substrate 100 between the first portions SPa. In other words, any portion of the first and second gate electrodes ELa and ELb or the first and second interlayer insulating layers ILDa and ILDb may not be left between the first portions SPa.

A side surface SPs of the separation structure SP may be in contact with the first and second gate electrodes ELa and ELb or the source structure SC which are adjacent thereto in the second direction D2. The side surface SPs of the separation structure SP may have a profile of an embossed line extending in the first direction D1. In some embodiments, the side surface SPs of the separation structure SP may include recesses that are arranged along and spaced apart from each other in the first direction D1, as illustrated in FIG. 5. In some embodiments, each of opposing side surfaces SPs of the separation structure SP may include recesses, and the separation structure SP may include narrow portions that are arranged along and spaced apart from each other in the first direction D1 and have a narrower width than adjacent portions thereof in the second direction D2, as illustrated in FIG. 5. In some embodiments, each of the recesses of a first one of the opposing side surfaces SPs may align with a respective one of the recesses of a second one of the opposing side surfaces SPs in the second direction D2 as illustrated in FIG. 5.

FIG. 9 is a graph showing a variation in doping concentration of an insulating layer covering a stack, in a three-dimensional semiconductor memory device according to an embodiment of the inventive concept.

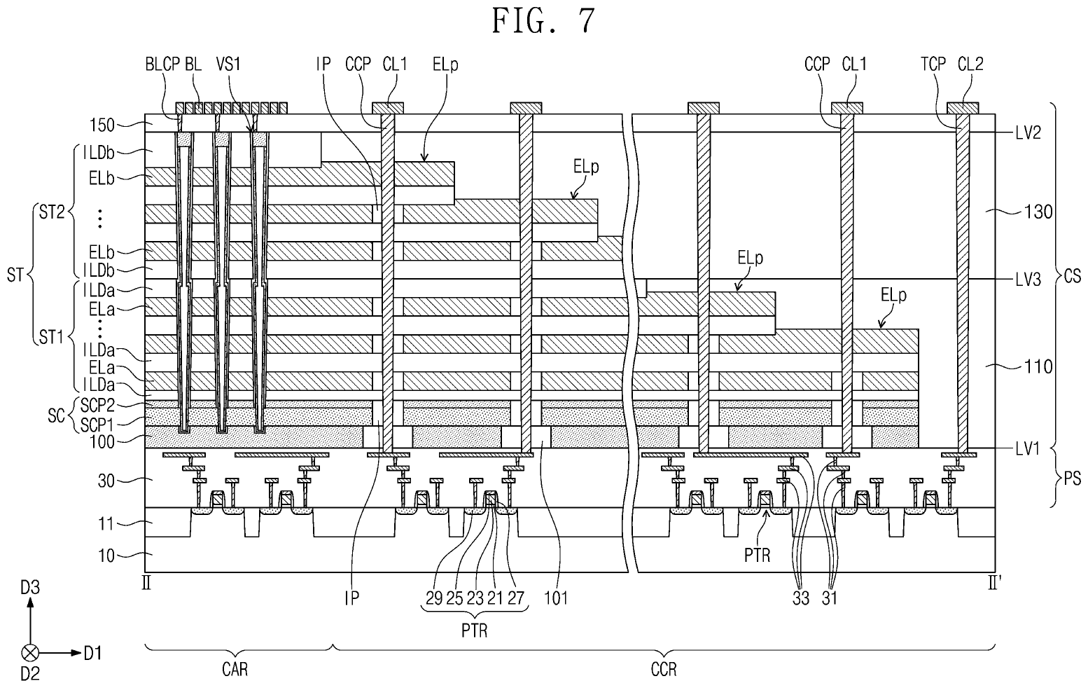

Referring to FIGS. 7 and 9, the second and third insulating layers 110 and 130 may have a non-uniform doping concentration. The doping concentration in the second insulating layer 110 may increase in the third direction D3 with decreasing distance from the second substrate 100. In other words, the second insulating layer 110 may have the highest doping concentration at the first level Lv1, and the second insulating layer 110 may have the lowest doping concentration at the third level Lv3. The doping concentration of the second insulating layer 110 may vary in a linear manner between the first level Lv1 and the third level Lv3. However, the inventive concept is not limited to this example, and in an embodiment, the doping concentration of the second insulating layer 110 may vary in a non-linear manner between the first level Lv1 and the third level Lv3.

The doping concentration in the third insulating layer 130 may increase in the third direction D3 with decreasing distance from the second substrate 100. In other words, the third insulating layer 130 may have the highest doping concentration at the third level Lv3 and the lowest doping concentration at the second level Lv2. The doping concentration of the third insulating layer 130 may vary in a linear manner between the third level Lv3 and the second level Lv2. However, the inventive concept is not limited to this example, and in an embodiment, the doping concentration of the third insulating layer 130 may vary in a non-linear manner between the third level Lv3 and the second level Lv2.

The doping concentration of the second insulating layer 110 at the third level Lv3 may be different from the doping concentration of the third insulating layer 130 at the third level Lv3. For example, the doping concentration of the second insulating layer 110 at the third level Lv3 may be lower than the doping concentration of the third insulating layer 130 at the third level Lv3. However, the inventive concept is not limited to this example, and in an embodiment, the doping concentration of the second insulating layer 110 at the third level Lv3 may be higher than or equal to the doping concentration of the third insulating layer 130 at the third level Lv3.

In an embodiment, each of the first and second interlayer insulating layers ILDa and ILDb may have substantially the same doping concentration as a portion of the second or third insulating layer 110 or 130 located at the same level.

FIG. 10 is an enlarged plan view illustrating a portion (e.g., A of FIG. 5) of a three-dimensional semiconductor memory device according to an embodiment of the inventive concept.

FIG. 10 illustrates a shape of a top surface of the separation structure SP, which can be seen from a sectional view that is made by horizontally cutting one of the first and second gate electrodes ELa and ELb to be parallel to the top surface of the second substrate 100.

Referring to FIGS. 5, 6, 8, and 10, a top surface of each of the first portions SPa of the separation structure SP may have an elliptical shape, a rectangular shape with four rounded corners, or a stadium shape, in which semicircles are connected to opposite sides of a rectangle. More specifically, the top surface of each of the first portions SPa may have an elliptical shape having a long axis of a first length L1 and a short axis of a second length L2. The first length L1 may be the largest length, in the first direction D1, of the top surface of each of the first portions SPa, and the second length L2 may be the largest length, in the second direction D2, of the top surface of each of the first portions SPa. The first length L1 and the second length L2 may range from about 90 nm to 130 nm. In an embodiment, the first length L1 may be larger than the second length L2.

The first portions SPa may be spaced apart from each other in the first direction D1, and in an embodiment, a distance G between the first portions SPa in the first direction D1 may range from about 30 nm to 70 nm. More specifically, the distance G between the first portions SPa in the first direction D1 may be defined as the shortest horizontal distance between side surfaces of the first portions SPa, which are adjacent to each other in the first direction D1. The distance G between the first portions SPa in the first direction D1 may decrease as a distance in the third direction D3 (or from a bottom surface of each of the first portions SPa) increases.

In an embodiment, a pitch P of the first portions SPa may range from about 120 nm to 200 nm. The pitch P of the first portions SPa may be equal to a sum of the first length L1 and the distance G. In an embodiment, the pitch P of the first portions SPa may be substantially equal to a pitch of the first vertical channel structures VS1 in the first direction D1 or a pitch of the second vertical channel structures VS2 in the first direction D1.

In an embodiment, an extension length Le, in the horizontal direction, of the second portion SPb, which extends from a side surface of each of the first portions SPa, may range from about 20 nm to 50 nm. In an embodiment, the extension length Le of the second portion SPb may be larger than or equal to about 30 nm. The extension length Le of the second portion SPb may be smaller than a distance between the side surface SPs of the separation structure SP and one of the first and second vertical channel structures VS1 and VS2, which is closest to the separation structure SP in the second direction D2. The extension length Le of the second portion SPb may be larger than or equal to half of the afore-described distance G between the first portions SPa in the first direction D1.

In an embodiment, the largest width Wm, in the second direction D2, of the top surface of the separation structure SP, which includes the first and second portions SPa and SPb, may range from about 110 nm to 210 nm. The largest width Wm, in the second direction D2, of the top surface of the separation structure SP may be equal to a sum of the second length L2 and a length, which is two times the extension length Le.

The separation structure SP may include at least one recessed portion DP, which is formed to have the smallest width in the second direction D2. The recessed portion DP of the separation structure SP may be positioned between the first portions SPa. Due to the presence of the recessed portion DP, the side surface SPs of the separation structure SP may have a profile of an embossed line extending in the first direction D1.

In an embodiment, atop surface of each of the first portions SPa of the separation structure SP may be shaped like a circle of a constant diameter. Here, the diameter of the top surface of each of the first portions SPa may be substantially equal to the diameter of the top surfaces of the first and second vertical channel structures VS1 and VS2. However, the inventive concept is not limited to this example, and in an embodiment, the top surface of each of the first portions SPa may have various shapes.

FIG. 11A is an enlarged view illustrating a portion (e.g., B of FIG. 6) of a three-dimensional semiconductor memory device according to an embodiment of the inventive concept.

FIG. 11A illustrates the source structure SC, which includes the first and second source conductive patterns SCP1 and SCP2, and one of the first vertical channel structures VS1, each of which includes the data storage pattern DSP, the vertical semiconductor pattern VSP, the gapfill insulating pattern VI, and the lower data storage pattern DSPr. For convenience in description, one of the stacks ST and one of the first vertical channel structures VS1 will be described, but the remaining ones of the stacks ST and the first vertical channel structures VS1 may have substantially the same features as those to be described hereinafter.

The data storage pattern DSP may include a blocking insulating layer BLK, a charge storing layer CIL, and a tunneling insulating layer TIL, which are sequentially stacked. The blocking insulating layer BLK may be adjacent to the stack ST or the source structure SC, and the tunneling insulating layer TIL may be adjacent to the vertical semiconductor pattern VSP. The charge storing layer CIL may be interposed between the blocking insulating layer BLK and the tunneling insulating layer TIL. The blocking insulating layer BLK may cover an inner side surface of each of the vertical channel holes CH (i.e., an inner side surface of the first vertical channel hole CHa).

The blocking insulating layer BLK, the charge storing layer CIL, and the tunneling insulating layer TIL may extend from a region between the stack ST and the vertical semiconductor pattern VSP in the third direction D3. In an embodiment, the Fowler-Nordheim (FN) tunneling phenomenon, which is caused by a voltage difference between the vertical semiconductor pattern VSP and the first and second gate electrodes ELa and ELb, may be used to store or change data in the data storage pattern DSP. In an embodiment, the blocking insulating layer BLK and the tunneling insulating layer TIL may be formed of or include silicon oxide, and the charge storing layer CIL may be formed of or include silicon nitride or silicon oxynitride.

The first source conductive pattern SCP1 of the source structure SC may be in contact with a side surface of the vertical semiconductor pattern VSP, and the second source conductive pattern SCP2 may be spaced apart from the vertical semiconductor pattern VSP with the data storage pattern DSP interposed therebetween. The first source conductive pattern SCP1 may be spaced apart from the gapfill insulating pattern VI with the vertical semiconductor pattern VSP interposed therebetween.

More specifically, the first source conductive pattern SCP1 may include protruding portions SCP1bt which are located at a level higher than a bottom surface SCP2b of the second source conductive pattern SCP2 or lower than a bottom surface SCP1b of the first source conductive pattern SCP1. However, the protruding portions SCP1bt may be located at a level lower than a top surface SCP2a of the second source conductive pattern SCP2. A surface of the protruding portion SCP1bt, which is in contact with the data storage pattern DSP or the lower data storage pattern DSPr, may have a curved shape.

FIG. 11B is an enlarged view illustrating a portion (e.g., B of FIG. 6) of a three-dimensional semiconductor memory device according to an embodiment of the inventive concept.

FIG. 11B illustrates one of the first vertical channel structures VS1, each of which includes the data storage pattern DSP, the vertical semiconductor pattern VSP, and the gapfill insulating pattern VI. For convenience in description, one of the stacks ST and one of the first vertical channel structures VS1 will be described, but the remaining ones of the stacks ST and the first vertical channel structures VS1 may have substantially the same features as those to be described hereinafter.

In the embodiment of FIG. 11B, unlike that shown in FIGS. 6, 7, and 11A, the source structure SC may not be provided between the second substrate 100 and the stack ST, and the bottom surface of the first vertical channel structure VS1 may be in direct contact with the top surface of the second substrate 100. The lowermost one of the first interlayer insulating layers ILDa may cover the top surface of the second substrate 100. More specifically, the vertical semiconductor pattern VSP of the first vertical channel structure VS1 may include a vertical portion VSPv, which extends from a region between the data storage pattern DSP and the gapfill insulating pattern VI in the third direction D3, and a horizontal portion VSPh, which extends from a region between the gapfill insulating pattern VI and the top surface of the second substrate 100 in the horizontal direction. The horizontal portion VSPh of the vertical semiconductor pattern VSP may extend along the top surface of the second substrate 100 and may be in direct contact with the second substrate 100.

Here, an upper portion of the second substrate 100 may be referred to as a source structure, and a conductive layer (e.g., including at least one of metal, metal silicide, or doped semiconductor materials) may be provided in the second substrate 100.

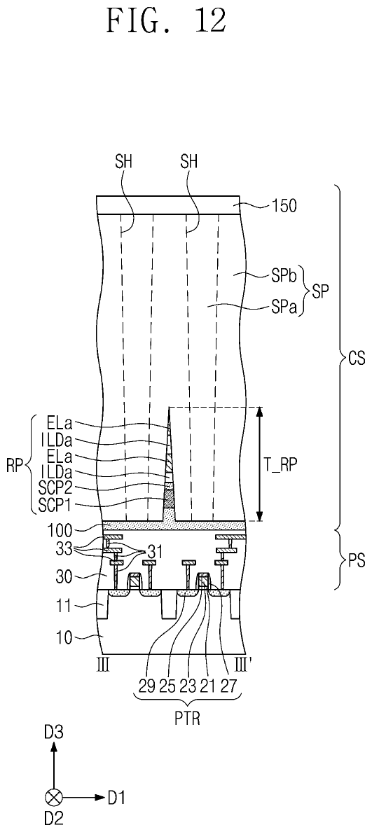

FIG. 12 is a sectional view illustrating a three-dimensional semiconductor memory device according to an embodiment of the inventive concept and corresponding to the line III-III′ of FIG. 5. In the following description, an element previously described with reference to FIGS. 5 to 8 may be identified by the same reference number without repeating an overlapping description thereof, for concise description.

Referring to FIG. 12, the second portion SPb between the first portions SPa may cover only a portion of the top surface of the second substrate 100. In other words, the first and second gate electrodes ELa and ELb or the first and second interlayer insulating layers ILDa and ILDb may be partially left between the first portions SPa, and the left portion of the first and second gate electrodes ELa and ELb or the first and second interlayer insulating layers ILDa and ILDb may be referred to as a remaining portion RP. The remaining portion RP may further include a portion of each of the first and second source conductive patterns SCP1 and SCP2. A width of the remaining portion RP in the first or second direction D1 or D2 may decrease as a height from the second substrate 100 in the third direction D3 increases. In an embodiment, a height T_RP of the remaining portion RP in the third direction D3 may be equal to or smaller than about 4 kÅ.

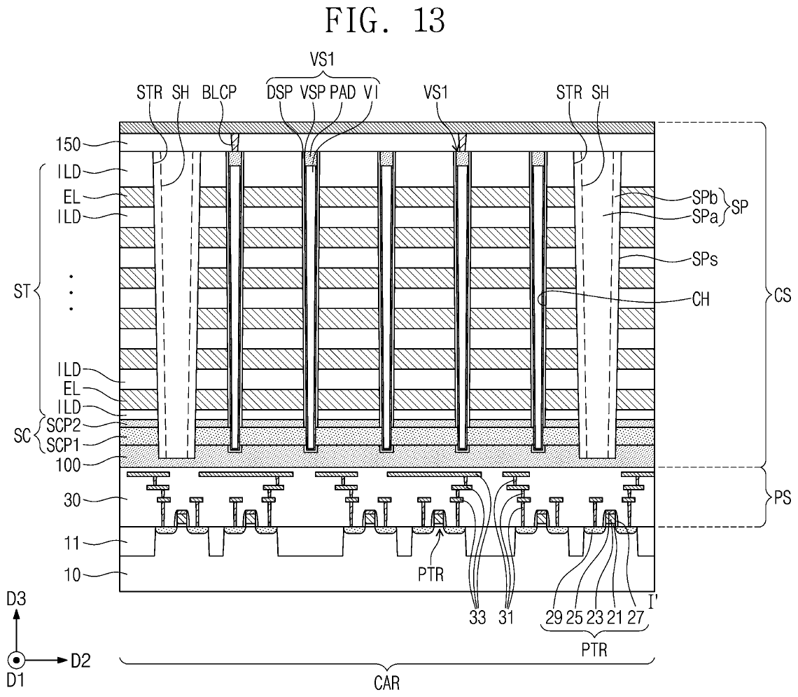

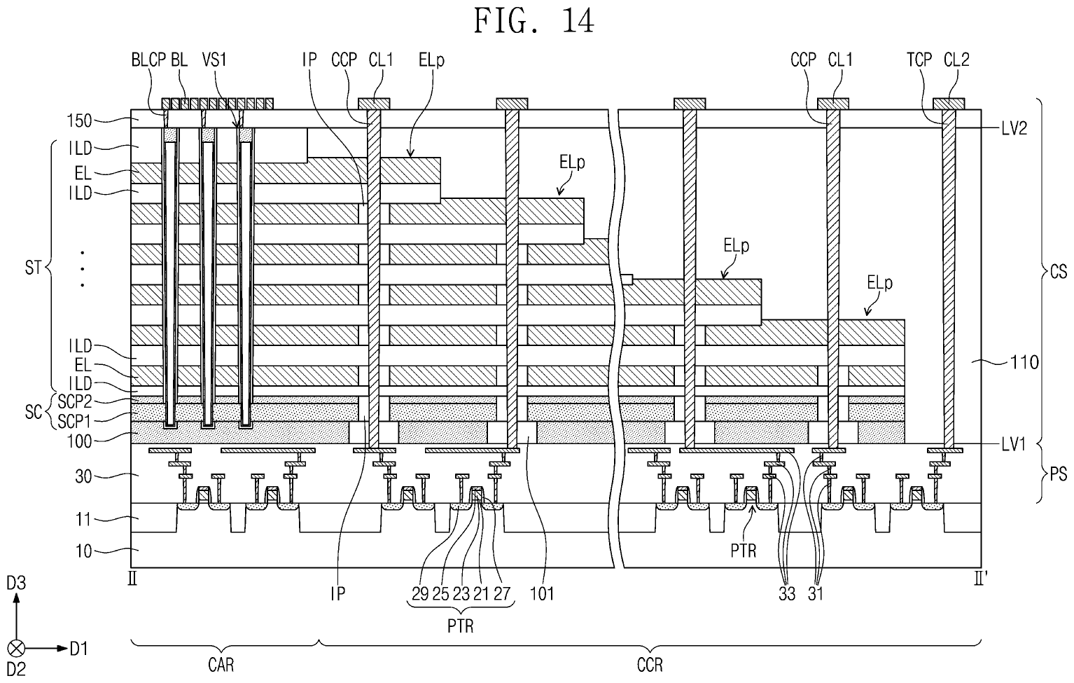

FIGS. 13 and 14 are sectional views illustrating a three-dimensional semiconductor memory device according to an embodiment of the inventive concept and corresponding to the lines I-I′ and II-II′ of FIG. 5. In the following description, an element previously described with reference to FIGS. 5 to 8 may be identified by the same reference number without repeating an overlapping description thereof, for concise description.

Referring to FIGS. 5, 13, and 14, the stack ST may include interlayer insulating layers ILD and gate electrodes EL, which are alternately and repeatedly stacked on the second substrate 100. The second insulating layer 110 may be provided on the second region CCR to cover the staircase structure of the stack ST. The top surface of the second insulating layer 110 may be substantially coplanar with the uppermost surface of the stack ST and the top surface of each of the first vertical channel structures VS1. The lowermost surface of the second insulating layer 110 may be located at the first level Lv1, and the uppermost surface of the second insulating layer 110 may be located at the second level Lv2. A side surface of each of the first vertical channel structures VS1 may have a flat shape without a stepped portion.

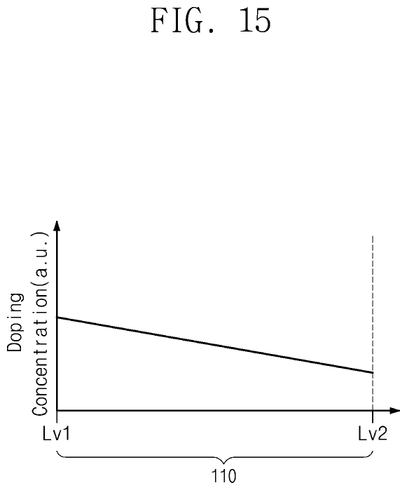

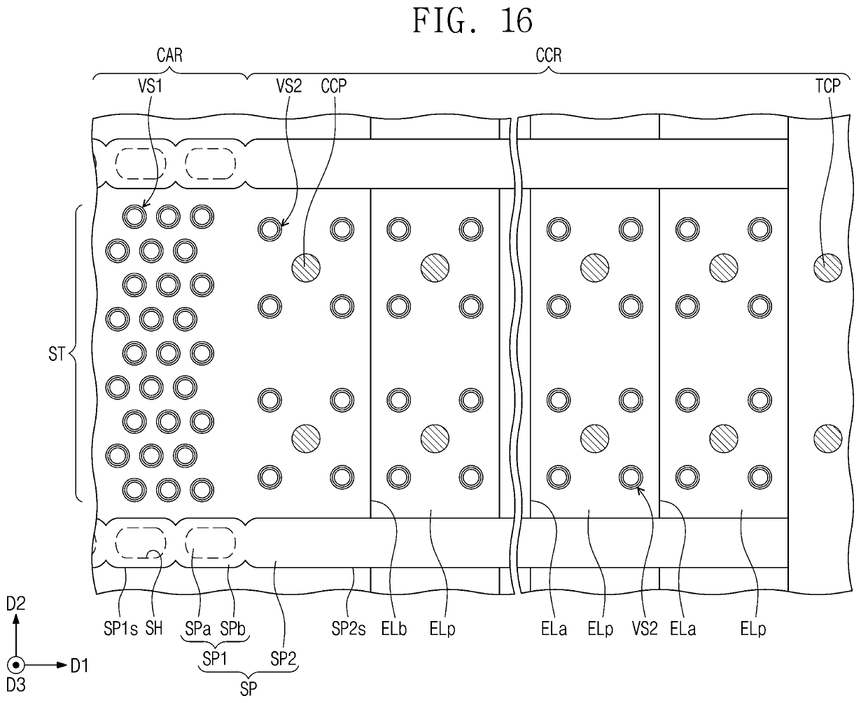

FIG. 15 is a graph showing a variation in doping concentration of an insulating layer covering a stack, in a three-dimensional semiconductor memory device according to an embodiment of the inventive concept.

Referring to FIGS. 14 and 15, the second insulating layer 110 may have a non-uniform doping concentration. The doping concentration in the second insulating layer 110 may increase with decreasing distance from the second substrate 100 in the third direction D3. For example, the second insulating layer 110 may have the highest doping concentration at the first level Lv1 and the lowest doping concentration at the second level Lv2. The doping concentration of the second insulating layer 110 may be linearly changed between the first and second levels Lv1 and Lv2. However, the inventive concept is not limited to this example, and in an embodiment, the doping concentration of the second insulating layer 110 may be non-linearly changed between the first and second levels Lv1 and Lv2.

FIG. 16 is a plan view illustrating a three-dimensional semiconductor memory device according to an embodiment of the inventive concept. In the following description, an element previously described with reference to FIGS. 5 to 8 may be identified by the same reference number without repeating an overlapping description thereof, for concise description.

Referring to FIG. 16, the separation structure SP may include a first separation structure SP1 on the first region CAR and a second separation structure SP2 on the second region CCR. The first separation structure SP1 on the first region CAR may include the first portions SPa, which are provided to fill the separation holes SH and to have a pillar shape extending in the third direction D3, and the second portion SPb, which is provided to enclose the first portions SPa in a plan view and to connect the first portions SPa to each other. In contrast, the second separation structure SP2 may have a flat plate shape that extends from the first separation structure SP1 in the first direction D1. In other words, a width of the second separation structure SP2 in the second direction D2 may be uniform along the first direction D1, and a side surface SP2s of the second separation structure SP2 may have a line-shaped profile that is parallel to the first direction D1. In some embodiments, the side surface SP2s of the second separation structure SP2 may be straight as illustrated in FIG. 16. Meanwhile, a width of the first separation structure SP1 in the second direction D2 may vary along the first direction D1, and a side surface SP1s of the first separation structure SP1 may have a profile of an embossed line extending in the first direction D1. In some embodiments, the side surface SP1s of the first separation structure SP1 may include multiple recesses arranged along the first direction D1 as illustrated in FIG. 16.

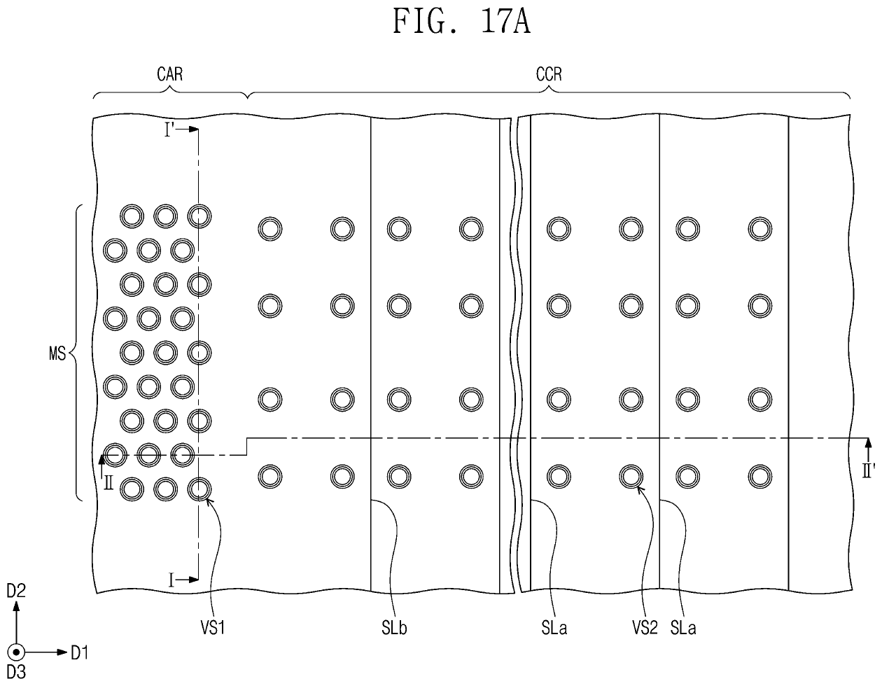

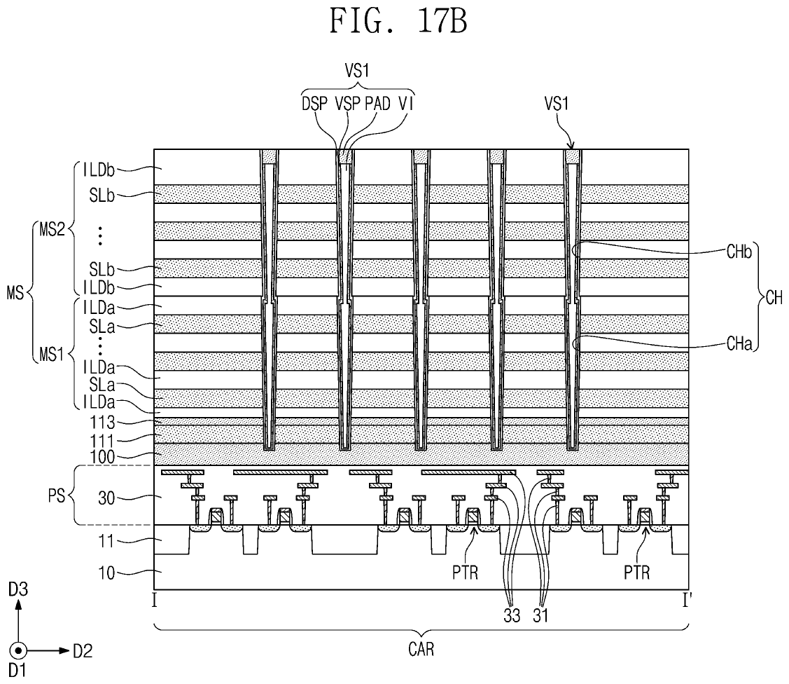

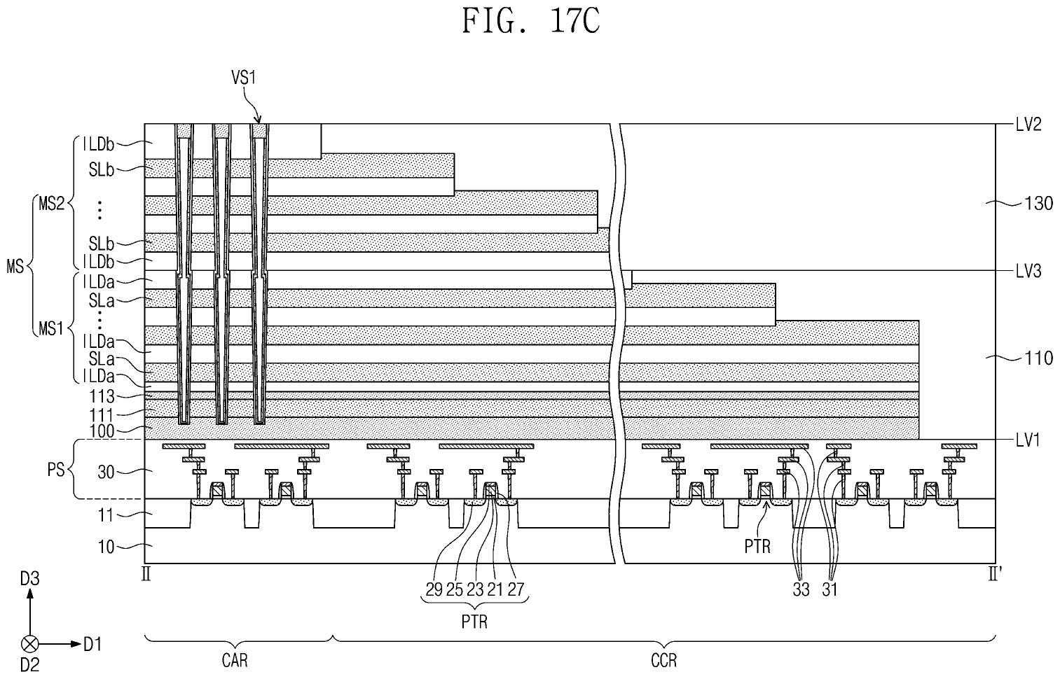

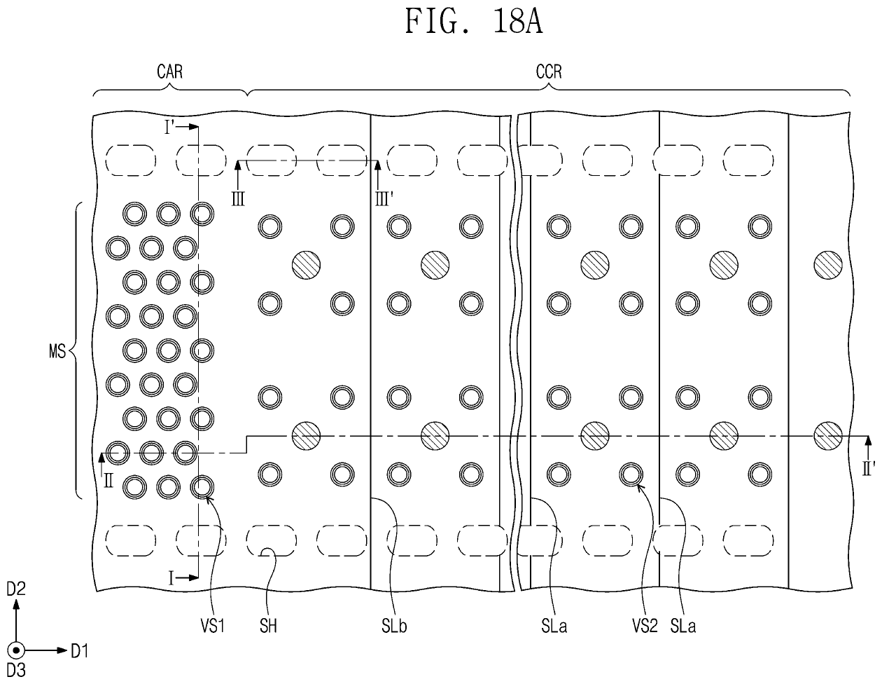

FIGS. 17A, 18A, and 19A are plan views illustrating a method of fabricating a three-dimensional semiconductor memory device according to an embodiment of the inventive concept. FIGS. 17B, 18B, and 19B are sectional views, which are respectively taken along lines I-I′ of FIGS. 17A, 18A, and 19A to illustrate a method of fabricating a three-dimensional semiconductor memory device according to an embodiment of the inventive concept. FIG. 17C is a sectional view, which is taken along a line II-II′ of FIG. 17A to illustrate a method of fabricating a three-dimensional semiconductor memory device according to an embodiment of the inventive concept. FIGS. 18C and 19C are sectional views, which are respectively taken along lines III-III′ of FIGS. 18A and 19A to illustrate a method of fabricating a three-dimensional semiconductor memory device according to an embodiment of the inventive concept.

Hereinafter, a method of fabricating a three-dimensional semiconductor memory device according to an embodiment of the inventive concept will be described in more detail with reference to FIGS. 17A to 17C, 18A to 18C, 19A to 19C, and 5 to 8.

Referring to FIGS. 17A, 17B, and 17C, the first substrate 10 including the first region CAR and the second region CCR may be provided. The device isolation layer 11 may be formed in the first substrate 10 to define an active region. The formation of the device isolation layer 11 may include forming a trench in an upper portion of the first substrate 10 and filling the trench with a silicon oxide layer.

The peripheral circuit transistors PTR may be formed on the active region defined by the device isolation layer 11. The peripheral contact plugs 31 and the peripheral circuit interconnection lines 33 may be formed to be connected to the peripheral source/drain regions 29 of the peripheral circuit transistors PTR. The first insulating layer 30 may be formed to cover the peripheral circuit transistors PTR, the peripheral contact plugs 31, and the peripheral circuit interconnection lines 33.

The second substrate 100 and the lower insulating patterns 101 (e.g., the lower insulating patterns 101 in FIG. 7) may be formed on the first insulating layer 30. The formation of the second substrate 100 and the lower insulating patterns 101 may include forming a semiconductor layer on the first insulating layer 30, patterning the semiconductor layer to expose a top surface of the first insulating layer 30, forming an insulating layer on the first insulating layer 30 and the semiconductor layer, and planarizing the insulating layer to expose a top surface of the semiconductor layer. As a result of the planarization process, the top surfaces of the lower insulating patterns 101 may be substantially coplanar with the top surface of the second substrate 100. In the following description, the expression of “two elements are substantially coplanar with each other” may mean that a planarization process may be performed on the elements. The planarization process may be performed using, for example, a chemical mechanical polishing (CMP) process or an etch-back process. The formation of the lower insulating patterns 101 may be performed to form a space, in which the first contact plugs CCP described above will be provided.

A portion of the second substrate 100 on the second region CCR may be removed. The partial removal of the second substrate 100 may include forming a mask pattern to cover the first region CAR and a portion of the second region CCR and patterning the second substrate 100 using the mask pattern. The partial removal of the second substrate 100 may be performed to form a space, in which the second contact plug TCP described above will be provided.

A lower sacrificial layer 111 and a lower semiconductor layer 113 may be formed on the second substrate 100. A first mold structure MS1 may be formed on the lower semiconductor layer 113. The formation of the first mold structure MS1 may include alternately and repeatedly stacking first interlayer insulating layers ILDa and first sacrificial layers SLa on the second substrate 100.

A first trimming process may be performed on the first mold structure MS1 on the second region CCR. The first trimming process may include forming a mask pattern on the first region CAR and the second region CCR to cover a portion of a top surface of the first mold structure MS1, patterning the first mold structure MS1 using the mask pattern as a patterning mask, reducing an area of the mask pattern, and patterning the first mold structure MS1 using the mask pattern having the reduced area as a patterning mask. In an embodiment, the steps of reducing the area of the mask pattern and patterning the first mold structure MS1 using the mask pattern may be repeated several times during the first trimming process. As a result of the first trimming process, the first mold structure MS1 may have a staircase structure.

The second insulating layer 110 may be formed on the second region CCR to cover the staircase structure of the first mold structure MS1 and a portion of the top surface of the first insulating layer 30. The formation of the second insulating layer 110 may include forming an insulating material to cover the staircase structure of the first mold structure MS1 and a portion of the top surface of the first insulating layer 30 and performing a planarization process to expose the top surface of the first mold structure MS1. The top surface of the second insulating layer 110 may be substantially coplanar with the top surface of the first mold structure MS1. After the formation of the second insulating layer 110, an impurity injection process may be performed on the first mold structure MS1 and the second insulating layer 110.

A second mold structure MS2 may be formed on the first mold structure MS1. The formation of the second mold structure MS2 may include alternately and repeatedly stacking second interlayer insulating layers ILDb and second sacrificial layers SLb on the first mold structure MS1.

A second trimming process may be performed on the second mold structure MS2 on the second region CCR. The second trimming process on the second mold structure MS2 may be performed in the same manner as the first trimming process on the first mold structure MS1, and as a result of the second trimming process, the second mold structure MS2 may have a staircase structure.

The third insulating layer 130 may be formed on the second region CCR to cover the staircase structure of the second mold structure MS2 and the second insulating layer 110. The formation of the third insulating layer 130 may include forming an insulating material to cover the staircase structure of the second mold structure MS2 and the top surface of the second insulating layer 110 and performing a planarization process to expose the top surface of the second mold structure MS2. The top surface of the third insulating layer 130 may be substantially coplanar with the top surface of the second mold structure MS2. After the formation of the third insulating layer 130, an impurity injection process may be performed on the second mold structure MS2 and the third insulating layer 130.

The first and second sacrificial layers SLa and SLb of the mold structure MS may be formed of an insulating material that is different from the first and second interlayer insulating layers ILDa and ILDb of the mold structure MS. The first and second sacrificial layers SLa and SLb may be formed of or include a material having an etch selectivity with respect to the first and second interlayer insulating layers ILDa and ILDb. For example, the first and second sacrificial layers SLa and SLb may be formed of silicon nitride, and the first and second interlayer insulating layers ILDa and ILDb may be formed of silicon oxide. The first and second sacrificial layers SLa and SLb may be formed to have substantially the same thickness, and the first and second interlayer insulating layers ILDa and ILDb may have at least two different thicknesses depending on their vertical positions.

The vertical channel holes CH may be formed to penetrate the mold structure MS, and the first and second vertical channel structures VS1 and VS2 may be formed to fill the vertical channel holes CH. On the first region CAR, the vertical channel holes CH may be formed to penetrate the mold structure MS, the lower semiconductor layer 113, and the lower sacrificial layer 111. On the second region CCR, the vertical channel holes CH may be formed to penetrate at least a portion of the second and third insulating layers 110 and 130, the mold structure MS, the lower semiconductor layer 113, and the lower sacrificial layer 111. The vertical channel holes CH may be formed to penetrate at least a portion of the second substrate 100, and in this case, a bottom surface of each of the vertical channel holes CH may be located at a level lower than the top surface of the second substrate 100.

The formation of the vertical channel holes CH may include forming the first vertical channel holes CHa to penetrate the first mold structure MS1, between the steps of forming the first and second mold structures MS1 and MS2, forming sacrificial pillars to fill the first vertical channel holes CHa, and forming the second vertical channel holes CHb to penetrate the second mold structure MS2 and to expose the sacrificial pillars in the first vertical channel holes CHa, after the step of forming the second mold structure MS2.

The formation of each of the first and second vertical channel structures VS1 and VS2 may include forming the data storage pattern DSP to conformally cover an inner side surface of each of the vertical channel holes CH, forming the vertical semiconductor pattern VSP to conformally cover a side surface of the data storage pattern DSP, forming the gapfill insulating pattern VI to fill at least a portion of a space enclosed by the vertical semiconductor pattern VSP, and forming the conductive pad PAD to fill a space enclosed by the vertical semiconductor pattern VSP and the gapfill insulating pattern VI.

Referring to FIGS. 18A, 18B, and 18C, the separation holes SH may be formed to penetrate the mold structure MS, the lower semiconductor layer 113, and the lower sacrificial layer 111. The separation holes SH may be provided to penetrate at least a portion of the second substrate 100, and in this case, a bottom surface of each of the separation holes SH may be located at a level lower than the top surface of the second substrate 100. For example, the bottom surface of each of the separation holes SH may be located at a level lower than the bottom surface of each of the vertical channel holes CH, but the inventive concept is not limited to this example. The separation holes SH, which are arranged in the first direction D1, may be spaced apart from each other in the first direction D1. Portions of the top surface of the second substrate 100 may be exposed to the outside through the separation holes SH.

After the formation of the separation holes SH, a portion of the mold structure MS may be left between the separation holes SH, which are spaced apart from each other in the first direction D1. Accordingly, even when a process of forming an additional supporting structure is omitted, it may be possible to prevent or suppress the mold structure MS from being collapsed.

Referring to FIGS. 19A, 19B, and 19C, the separation holes SH may be enlarged by a wet etching process using etching solution. During the enlargement of the separation holes SH, the first and second interlayer insulating layers ILDa and ILDb and the first and second sacrificial layers SLa and SLb of the mold structure MS may be partially removed to form a separation trench STR that extends in the first direction D1. The stacks ST may be spaced apart from each other in the second direction D2 with the separation trench STR interposed therebetween.

Referring back to FIGS. 5 to 8, the sacrificial layers 111, SLa, and SLb exposed by the separation trench STR may be selectively removed. The selective removal of the sacrificial layers 111, SLa, and SLb may be performed by a wet etching process using etching solution. The selective removal of the sacrificial layers 111, SLa, and SLb may be performed to form a first gap region, from which the lower sacrificial layer 111 is removed, and second gap regions, from which the first and second sacrificial layers SLa and SLb are removed. In an embodiment, the first gap region may extend to a side surface of the vertical semiconductor pattern VSP of each of the first and second vertical channel structures VS1 and VS2. For example, the process of removing the lower sacrificial layer 111 (or an additional etching process) may be performed to partially remove the data storage pattern DSP of each of the first and second vertical channel structures VS1 and VS2 and to expose the side surface of the vertical semiconductor pattern VSP.

The first source conductive pattern SCP1 may be formed to fill an inner space of the first gap region. In an embodiment, the first source conductive pattern SCP1 may be formed of or include at least one of doped semiconductor materials. In an embodiment, an air gap may be formed in the first source conductive pattern SCP1. The lower semiconductor layer 113 may be referred to as the second source conductive pattern SCP2, and in this case, the source structure SC including the first and second source conductive patterns SCP1 and SCP2 may be formed. For example, the selective removal of the first and second sacrificial layers SLa and SLb may be performed after the formation of the source structure SC.

The first and second gate electrodes ELa and ELb may be formed to fill an inner space of the second gap regions. As a result, the stack ST including the first and second gate electrodes ELa and ELb and the first and second interlayer insulating layers ILDa and ILDb may be formed.

The separation structure SP may be formed to fill the separation trench STR. The separation structure SP may be formed of or include at least one of insulating materials (e.g., silicon oxide, silicon nitride, or silicon oxynitride). In an embodiment, the separation structure SP may have a single object structure, which is formed of a single insulating material.

The fourth insulating layer 150 may be formed to cover the mold structure MS, the third insulating layer 130, and the separation structure SP. The fourth insulating layer 150 may cover the top surfaces of the first and second vertical channel structures VS1 and VS2.

The bit line contact plugs BLCP may be formed to penetrate the fourth insulating layer 150. The first contact plugs CCP may be formed to penetrate the fourth insulating layer 150, at least a portion of the second and third insulating layers 110 and 130, the stack ST, the source structure SC, and corresponding ones of the lower insulating patterns 101. The second contact plug TCP may be formed to penetrate the second to fourth insulating layers 110, 130, and 150 and at least a portion of the first insulating layer 30 and may be electrically connected to the peripheral circuit transistors PTR of the peripheral circuit structure PS.

The bit lines BL may be formed on the fourth insulating layer 150 to be connected to corresponding ones of the bit line contact plugs BLCP. In addition, the first conductive lines CL1 may be formed on the fourth insulating layer 150 to be connected to the first contact plugs CCP, and the second conductive line CL2 may be formed on the fourth insulating layer 150 to be connected to the second contact plug TCP. In an embodiment, additional interconnection lines and additional vias, which are electrically connected to the bit lines BL and the first and second conductive lines CL1 and CL2, may be formed on the fourth insulating layer 150.

According to an embodiment of the inventive concept, vertical channel holes, in which vertical channel structures are provided, and a separation hole, in which a portion of a separation structure is provided, may be formed at the same time, and thus, it may be possible to reduce the number and difficulty of etching processes. In addition, after the formation of the separation holes, a portion of a mold structure may be left between the separation holes, and thus, it may be possible to prevent or suppress the mold structure from being collapsed even when a process of forming an additional supporting structure is omitted. Accordingly, it may be possible to simplify a process of fabricating a three-dimensional semiconductor memory device and to improve electric and reliability characteristics of the three-dimensional semiconductor memory device.

According to an embodiment of the inventive concept, an insulating layer covering a staircase structure of a stack may be doped with impurities, and here, the insulating layer may be formed to have a varying doping concentration. Thus, it may be possible to increase a removal amount of the mold structure in a process of enlarging the separation holes and to prevent or suppress a bowing phenomenon from occurring in the separation holes.

While example embodiments of the inventive concept have been particularly shown and described, it will be understood by one of ordinary skill in the art that variations in form and detail may be made therein without departing from the scope of the attached claims.

What is claimed is:

1. A three-dimensional semiconductor memory device, comprising:
a substrate including a first region and a second region;
first and second stacks, each of which includes interlayer insulating layers and gate electrodes stacked alternately with the interlayer insulating layers on the substrate and has a stepped structure on the second region;
an insulating layer on the stepped structure of the first stack;
a plurality of vertical channel structures on the first region to penetrate the first stack; and
a separation structure separating the first and second stacks from each other,
wherein the insulating layer comprises one or more dopants, and
a dopant concentration of the insulating layer decreases as a distance from the substrate increases.

2. The three-dimensional semiconductor memory device of claim 1, wherein the separation structure extends longitudinally in a first direction, and a side surface of the separation structure comprises a plurality of recesses arranged along the first direction.

3. The three-dimensional semiconductor memory device of claim 1, wherein the separation structure has a unitary structure including a single insulating material.

4. The three-dimensional semiconductor memory device of claim 1, wherein the dopant concentration of the insulating layer varies linearly as the distance from the substrate increases.

5. The three-dimensional semiconductor memory device of claim 1, wherein the one or more dopants comprise N, F, P, B, C, Ge, As, Cl, and/or Br.

6. The three-dimensional semiconductor memory device of claim 1, wherein the insulating layer comprises a first doped insulating material, and
each of the interlayer insulating layers comprises a second doped insulating material.

7. The three-dimensional semiconductor memory device of claim 1, further comprising a remaining portion that is between the substrate and the separation structure and comprises a portion of the interlayer insulating layers and a portion of the gate electrodes of the first stack, and
the remaining portion has a width decreasing as a distance from the substrate increases.

8. The three-dimensional semiconductor memory device of claim 7, wherein a height of the remaining portion is smaller than or equal to 4 kÅ.

9. The three-dimensional semiconductor memory device of claim 1, wherein the first stack comprises a lower stack comprising a lower stepped structure on the substrate and an upper stack comprising an upper stepped structure on the lower stack,
the insulating layer comprises a first insulating layer on the lower stepped structure of the lower stack, and a second insulating layer on the upper stepped structure of the upper stack, and
a dopant concentration in each of the first and second insulating layers decreases as a distance from the substrate increases.

10. The three-dimensional semiconductor memory device of claim 9, wherein the dopant concentration in an uppermost portion of the first insulating layer is higher than the dopant concentration of a lowermost portion of the second insulating layer.

11. The three-dimensional semiconductor memory device of claim 9, wherein a side surface of each of the vertical channel structures has a stepped portion adjacent an interface between the first and second insulating layers.

12. The three-dimensional semiconductor memory device of claim 1, wherein the separation structure extends longitudinally in a first direction and comprises a first separation structure on the first region and a second separation structure that is on the second region and extends from the first separation structure in the first direction, and
the second separation structure comprises a straight side surface extending in the first direction.

13. The three-dimensional semiconductor memory device of claim 12, wherein a width of the second separation structure in a second direction that is perpendicular to the first direction is substantially uniform along the first direction.

14. The three-dimensional semiconductor memory device of claim 1, further comprising a source structure between the substrate and the first stack,
wherein each of the vertical channel structures comprises a data storage pattern and a vertical semiconductor pattern in the data storage pattern, and
the source structure is in contact with the vertical semiconductor pattern of each of the vertical channel structures.

15. The three-dimensional semiconductor memory device of claim 14, wherein the source structure is in contact with a side surface of the vertical semiconductor pattern of each of the vertical channel structures.

16. A three-dimensional semiconductor memory device, comprising:
a first substrate including a first region and a second region;
a peripheral circuit structure including peripheral circuit transistors on the first substrate;
a second substrate on the peripheral circuit structure and on the first region and the second region of the first substrate;
lower insulating patterns in the second substrate;
first and second stacks, each of which includes interlayer insulating layers and gate electrodes stacked alternately with the interlayer insulating layers on the second substrate and the lower insulating patterns and has a stepped structure on the second region;
a source structure between the second substrate and the first stack;
an insulating layer on the stepped structure of the first stack;
a plurality of vertical channel structures on the first region of the first stack, penetrate the first stack and in contact with the second substrate;
a first contact plug that is on the second region and penetrates the insulating layer, the first stack, the source structure, and one of the lower insulating patterns, wherein the first contact plug is electrically connected to a first one of the peripheral circuit transistors of the peripheral circuit structure and is in contact with one of the gate electrodes of the first stack;
a second contact plug that is on the second region to penetrate the insulating layer and is electrically connected to a second one of the peripheral circuit transistors of the peripheral circuit structure; and
a separation structure separating the first and second stacks from each other and extending in a first direction,
wherein the separation structure comprises opposing side surfaces, each of which comprises a recess, and the recesses of the opposing side surfaces of the separation structure are aligned with each other along a second direction crossing the first direction and define a narrow portion having a narrower width than adjacent portions thereof in the second direction, and
the insulating layer comprises one or more dopants.

17. The three-dimensional semiconductor memory device of claim 16, wherein a dopant concentration of the insulating layer decreases as a distance from the substrate increases.

18. The three-dimensional semiconductor memory device of claim 16, wherein the first and second contact plugs have bottom surfaces that are located at a level lower than a bottom surface of the first stack.

19. The three-dimensional semiconductor memory device of claim 16, wherein each of the gate electrodes comprises a pad portion having a first thickness on the second region and an electrode portion having a second thickness on the first region,
the first thickness of the pad portion is thicker than the second thickness of the electrode portion, and
the first contact plug penetrates one of the pad portions and is in contact with the one of the pad portions.

20. An electronic system, comprising:
a three-dimensional semiconductor memory device; and
a controller electrically connected to the three-dimensional semiconductor memory device and configured to control the three-dimensional semiconductor memory device,
wherein the three-dimensional semiconductor memory device comprises:
a substrate including a first region and a second region;
first and second stacks, each of which includes interlayer insulating layers and gate electrodes stacked alternately with the interlayer insulating layers on the substrate and has a stepped structure on the second region;
an insulating layer on the stepped structure of the first stack;
a plurality of vertical channel structures on the first region and penetrate the first stack; and
a separation structure separating the first and second stacks from each other,
wherein the insulating layer comprises one or more dopants, and
a dopant concentration of the insulating layer decreases as a distance from the substrate increases.
